(19) United States
(12) Patent Application Publication
(10) Pub. No.: US 2026/0358927 A1
(43) Pub. Date: Nov. 12, 2026

(54) TOUCH-SENSITIVE APPARATUS AND METHOD

(71) Applicant: TouchNetix Limited, Fareham, Hampshire (GB)

(72) Inventors: Peter Timothy SLEEMAN, Fareham, Hampshire (GB); Stephen William ROBERTS, Fareham, Hampshire (GB); Trond Jarle PEDERSEN, Fareham, Hampshire (GB)

(73) Assignee: TouchNetix Limited, Fareham, Hampshire (GB)

(21) Appl. No.: 19/118,218

(22) PCT Filed: Oct. 17, 2023
(86) PCT No.: PCT/GB2023/052685

§ 371 Date: Apr. 3, 2025

(30) Foreign Application Priority Data
Oct. 19, 2022 (GB) 2215440.5

(51) Int. Cl. G06F 3/044; G06F 3/041

(52) U.S. Cl. CPC G06F 3/0446; G06F 3/0416

(57) ABSTRACT

Disclosed is a touch-sensitive system, the system including: a sensing element comprising at least one electrode, the sensing element comprising a sensing surface for sensing the interaction of a touch or object with the sensing element; a user identification electrode arranged so as to be capable of capacitively coupling to a user of the touch-sensitive system; drive circuitry configured to generate a first drive signal and a second drive signal; and control circuitry. The control circuitry is configured to: identify a set of N electrodes of the sensing element; apply one of the first drive signal or second drive signal to each of the set of N electrodes and to the user identification electrode; obtain a measurement from the sensing element in each of a plurality of discrete time periods; and determine whether a detected touch or object at the sensing surface results from a user.

### BACKGROUND OF THE INVENTION

The present invention relates to the field of touch sensors, for example touch sensors for overlying a display screen to provide a touch-sensitive display (touch screen). In particular, embodiments of the invention relate to techniques for measuring the mutual capacitance at a plurality of intersections between drive electrodes and receive electrodes for sensing the presence of one or more touching objects within a two-dimensional sensing area.

A capacitive touch sensor can be generalised as one that uses a physical sensor element comprising an arrangement of electrically conductive electrodes extending over a touch sensitive area (sensing area) to define sensor nodes (or intersection points) and controller circuitry connected to the electrodes and operable to measure changes in the electrical capacitance of each of the electrodes or the mutual-capacitance between combinations of the electrodes. The electrodes are typically provided on a substrate. Some of these electrodes may be referred to as drive electrodes (which are driven with a suitable signal, such as a time-varying voltage signal) and some may be referred to as receive electrodes (which are coupled to receiver circuitry and generate a signal in response to a driven drive electrode coupling to the receiver electrode at the sensor node).

While such conventional systems have certain advantages, one disadvantage with such techniques is the ability to distinguish between different user's or different objects interacting with the capacitive touch sensor. Indeed, in the above example where the electrode array is driven by a signal applied to the electrode array, when two users interact with the electrode array in substantially the same manner, the way in which the driven electrode array is affect is substantially the same regardless of the user that is interacting with the electrode array. Hence, conventional systems are largely incapable of distinguishing between inputs received from different users.

There is therefore a desire to provide touch sensors or systems with the ability to differentiate between touches (inputs) received from different users.

### SUMMARY OF THE INVENTION

According to a first aspect of the invention there is provided a touch-sensitive system, the system including: a sensing element comprising at least one electrode, the sensing element comprising a sensing surface for sensing the interaction of a touch or object with the sensing element; a user identification electrode arranged so as to be capable of capacitively coupling to a user of the touch-sensitive system; drive circuitry configured to generate a first drive signal and a second drive signal, wherein the first and second drive signals are the inverse of one another; and control circuitry configured to: identify a set of N electrodes of the sensing element, where N is an integer greater than or equal to one, the set of N electrodes including the at least one electrode; apply one of the first drive signal or second drive signal to each of the set of N electrodes and to the user identification electrode over a plurality of discrete time periods, wherein the drive signal applied to the at least one electrode or the user identification electrode in a first time period of the plurality of discrete time periods is different to the drive signal applied to the at least one electrode or the user identification electrode in a second time period of the plurality of discrete time periods; obtain a measurement from the sensing element in each of the plurality of discrete time periods; and determine whether a detected touch or object at the sensing surface results from a user capacitively coupled to the user identification electrode based on the obtained measurements from the sensing element in each of the plurality of discrete time periods.

According to a second aspect of the invention there is provided a host system comprising the touch-sensitive system of the first aspect, further comprising host system processing circuitry communicatively coupled to the control circuitry of the touch-sensitive system, wherein the host system processing circuitry is configured to receive an output signal from the control circuitry of the touch-sensitive system indicative of whether a detected touch or object results from a user capacitively coupled to the user identification electrode.

According to a third aspect of the invention there is provided a vehicle comprising the host system of the second aspect, wherein the user identification electrode is mounted to an electrically conductive component of a seat, wherein the electrically conductive component is arranged to contact a user when the user is sitting in the seat.

According to a fourth aspect of the invention there is provided a method of operating a touch-sensitive system, the system comprising a sensing element comprising at least one electrode, the sensing element comprising a sensing surface for sensing the interaction of a touch or object with the sensing element; a user identification electrode arranged so as to be capable of capacitively coupling to a user of the touch-sensitive system; and drive circuitry configured to generate a first drive signal and a second drive signal, wherein the first and second drive signals are the inverse of one another, wherein the method includes: identifying a set of N electrodes of the sensing element, where N is an integer greater than or equal to one, the set of N electrodes including the at least one electrode; applying one of the first drive signal or second drive signal to each of the set of N electrodes and to the user identification electrode over a plurality of discrete time periods, wherein the drive signal applied to the user identification electrode in a first time period of the plurality of discrete time periods is different to the drive signal applied to the user identification electrode in a second time period of the plurality of discrete time periods; obtaining a measurement from the sensing element in each of the plurality of discrete time periods; and determining whether a detected touch or object at the sensing surface results from a user capacitively coupled to the user identification electrode based on the obtained measurements from the sensing element in each of the plurality of discrete time periods.

It will be appreciated that features and aspects of the invention described above in relation to the first and other aspects of the invention are equally applicable to, and may be combined with, embodiments of the invention according to other aspects of the invention as appropriate, and not just in the specific combinations described above.

### BRIEF DESCRIPTION OF THE DRAWINGS

The invention is now described by way of example only with reference to the following drawings in which:

FIG. 1 schematically illustrates an example touch sensitive apparatus in accordance with certain embodiments of the invention;

FIG. 2 schematically illustrates the mutual-capacitance type a touch sensitive apparatus of FIG. 1 in more detail, specifically with a view to explaining the principles of mutual capacitance measurement;

FIG. 3 schematically illustrates a conventional mutual-capacitance type touchscreen apparatus for explaining the measurement steps associated with a conventional mutual-capacitance type touchscreen;

FIG. 4 schematically illustrates the drive circuitry of the touch sensitive apparatus of FIG. 1 in more detail in accordance with certain embodiments of the invention;

FIGS. 5a to 5d schematically illustrates a part of an electrode array of a touch sensitive apparatus for explaining measurement techniques utilising a plurality of drive signals;

FIG. 6 schematically illustrates a touch sensitive system in accordance with certain embodiments of the invention, the touch sensitive system including the touch-sensitive apparatus of FIG. 1 in addition to a user identification electrode arranged to capacitively couple to a user of the touch sensitive system;

FIGS. 7a to 7d schematically illustrates a part of an electrode array of a touch sensitive apparatus for explaining measurement techniques utilising a plurality of drive signals and for obtaining a signal indicative of whether a detected touch or object at the sensing surface results from a user capacitively coupled to the user identification electrode in accordance with certain embodiments of the invention;

FIG. 8 schematically illustrates an example system of a vehicle which employs the touch sensitive system of FIG. 7 in accordance with certain embodiments of the invention;

FIG. 9 schematically shows the touch sensitive apparatus of FIG. 1 in which a first touch provided by a user coupled to the user identification electrode and a second touch provided by a user not coupled to the user identification electrode is schematically illustrated for explaining the principles of a touch tracking module in accordance with implementations of the invention; and

FIG. 10 shows a method for detecting a touch and obtaining a signal indicative of whether a detected touch or object at the sensing surface results from a user capacitively coupled to the user identification electrode using a touch sensitive system in accordance with certain embodiments of the invention.

### DETAILED DESCRIPTION

The present invention relates to a touch sensitive system which provides a region (a sensing surface) that is sensitive to a user's touch and/or an object held by a user. Such a touch sensitive system utilises a capacitance sensing technique (such as a mutual capacitance sensing technique) in which capacitances associated with one or more electrodes forming an electrode array are capable of being measured either directly or indirectly. More specifically, the present invention comprises a user identification electrode arranged so as to be capable of capacitively coupling to a user of the touch-sensitive system, e.g., through direct or indirect contact with the user. The user identification electrode is used to provide a signal to a user, such that when the user interacts with (touches) the sensing surface of the touch sensitive system, the signal couples to the electrode(s) of the electrode array and is subsequently capable of being detected in measurements of the electrode array (i.e., any capacitance based measurements). This enables the detection of a specific user interaction (namely the user that is capacitively coupled to the user identification electrode) and subsequently the association of any detected touches with that user. Accordingly, detected touches can be allocated to a given user and any circuitry that utilises the touch sensitive system as an input mechanism can perform different actions based on whether the input (the touch) is determined to result from the user capacitively coupled to the user identification electrode interacting with the sensing surface. In addition, driving of the user identification electrode with the drive signal is performed as part of a process to drive electrodes of the electrode array, specifically such that combinations of resulting measurements made from the electrode array are able to provide signals indicative of the capacitances of individual electrodes/pairs of electrodes or the presence of a signal from the user identification electrode. More specifically, a set of N electrodes of the sensing element, where N is an integer greater than or equal to one, and the user identification electrode are driven by one of a first drive signal or a second drive signal (where only one of the signals are applied to any of the aforementioned electrodes at any given time). The drive signal applied to at least one electrode or the user identification electrode in a first time period is different to the drive signal applied to the at least one electrode or the user identification electrode in a second time period. The technique of driving groups of electrodes in conjunction with the user identification electrode offers benefits in terms of the responsiveness and/or sensitivity of the touch sensitive system in respect of detecting touches at the sensing surface, but additionally also enables the signal indicative of the interaction of the user capacitive coupled to the user identification electrode to be measured at the same time as the measurements used to determine the presence or absence of a touch. This allows for an accurate determination as to whether the detected touch is likely to have resulted from the user capacitively coupled to the user identification electrode.

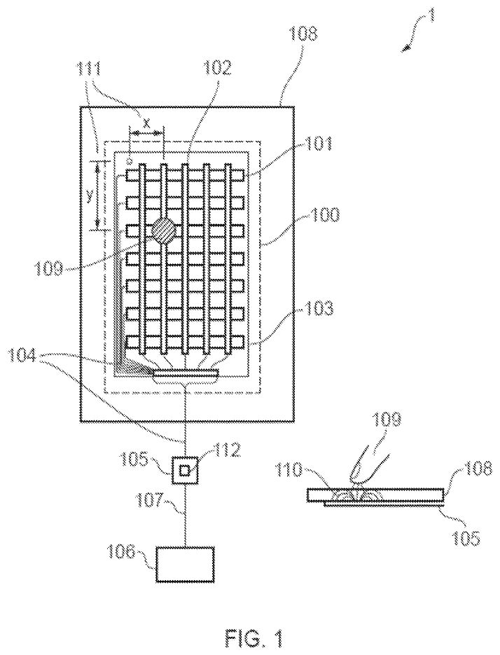

FIG. 1 schematically shows a touch-sensitive apparatus 1 in accordance with aspects of the present disclosure. The touch-sensitive apparatus 1 is represented in plan view (to the left in the figure) and also in cross-sectional view (to the right in the figure).

The touch-sensitive apparatus 1 comprises a sensor element 100, measurement circuitry 105, processing circuitry 106, and cover 108. The sensor element 100 and cover 108 may, more generally be referred to as a touch screen or touch-sensitive element of the touch-sensitive apparatus 1, while the measurement circuitry 105 and processing circuitry 106 may, more generally, be referred to as the controller or control circuitry of the touch-sensitive apparatus 1.

The touch screen is primarily configured for establishing the position of a touch within a two-dimensional sensing area by providing Cartesian coordinates along an X-direction (horizontal in the figure) and a Y-direction (vertical in the figure). In this implementation, the sensor element 100 is constructed from a substrate 103 that could be glass or plastic or some other insulating material and upon which is arranged an array of electrodes consisting of multiple laterally extending parallel electrodes, X-electrodes 101 (row electrodes), and multiple vertically extending parallel electrodes, Y-electrodes 102 (column electrodes), which in combination allow the position of a touch 109 to be determined. To clarify the terminology, and as will be seen from FIG. 1, the X-electrodes 101 (row electrodes) are aligned parallel to the X-direction and the Y-electrodes 102 (column electrodes) are aligned parallel to the Y-direction. Thus the different X-electrodes allow the position of a touch to be determined at different positions along the Y-direction while the different Y-electrodes allow the position of a touch to be determined at different positions along the X-direction. That is to say in accordance with the terminology used herein, the electrodes are named (in terms of X- and Y-) after their direction of extent rather than the direction along which they resolve position. Furthermore, the electrodes may also be referred to as row electrodes and column electrodes. It will however be appreciated these terms are simply used as a convenient way of distinguishing the groups of electrodes extending in the different directions. In particular, the terms are not intended to indicate any specific electrode orientation. In general the term “row” will be used to refer to electrodes extending in a horizontal direction for the orientations represented in the figures while the terms “column” will be used to refer to electrodes extending in a vertical direction in the orientations represented in the figures. The X-electrodes 101 and Y-electrodes 102 define a sensing (or sense) area, which is a region of the substrate 103 which is sensitive to touch.

In some cases, each electrode may have a more detailed structure than the simple “bar” structures represented in FIG. 1, but the operating principles are broadly the same. The sensor electrodes are made of an electrically conductive material such as copper or Indium Tin Oxide (ITO). The nature of the various materials used depends on the desired characteristics of the touch screen. For example, a touch screen may need to be transparent, in which case ITO electrodes and a plastic substrate are common. On the other hand a touch pad, such as often provided as an alternative to a mouse in laptop computers is usually opaque, and hence can use lower cost copper electrodes and an epoxy-glass-fibre substrate (e.g. FR4).

Referring back to FIG. 1, the electrodes 101, 102 are electrically connected via circuit conductors 104 to measurement circuitry 105, which is in turn connected to processing circuitry 106 by means of circuit conductors 107. The measurement circuitry 105 and/or the processing circuitry 106 may each be provided by a (micro)controller, processor, ASIC or similar form of control chip. Although shown separately in FIG. 1, in some implementations, the measurement circuitry and the processing circuitry may be provided by the same (micro)controller, processor, ASIC or similar form of control chip. The measurement circuitry 105 and/or the processing circuitry 106 may be comprised of a printed circuit board (PCB), which may further include the various circuit conductors 104, 107. The measurement circuitry 105 and the processing circuitry 106 may be formed on the same PCB, or separate PCBs. Note also that the functionality provided by either of the measurement circuitry 105 and the processing circuitry 106 may be split across multiple circuit boards and/or across components which are not mounted to a PCB. The processing circuitry 106 interrogates the measurement circuitry 105 to recover the presence and coordinates of any touch or touches present on, or proximate to, the sensor element 100.

Generally speaking, the measurement circuitry 105 is configured to perform capacitance measurements associated with the electrodes 101, 102 (described in more detail below). The measurement circuitry 105 comprises drive circuitry 112 for generating electrical signals for performing the capacitance measurements. The measurement circuitry 105 outputs the capacitance measurements to the processing circuitry 106, which is arranged to perform processing using the capacitance measurements. The processing circuitry 106 may be configured to perform a number of functions, but at the very least is configured to determine when a touch 109, caused by an object such a human finger or a stylus coming into contact with (or being adjacent to) the sense area of the sensor element 100 with appropriate analysis of relative changes in the electrodes' measured capacitance/capacitive coupling. This determination process is described in more detail below. The processing circuitry 106, as in the described implementation, may also be configured to, with appropriate analysis of relative changes in the electrodes' measured capacitance/capacitive coupling, calculate a touch position on the cover's surface as an X-Y coordinate 111.

In the example, a front cover (also referred to as a lens or panel) 108 is positioned in front of the substrate 103 and a single touch 109 on the surface of the cover 108 is schematically represented. Note that the touch itself does not generally make direct galvanic connection to the sensor 103 or to the electrodes 102. Rather, the touch influences the electric fields 110 that the measurement circuitry 105 generates using the electrodes 102 (described in more detail below).

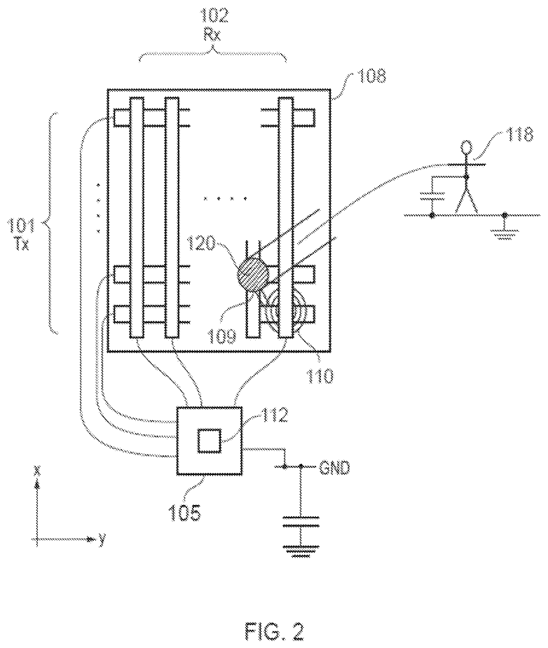

The measurement circuitry 105 of the described implementation is configured to measure the capacitance of the electrodes using a technique that is based on measuring what is frequently referred to as “mutual-capacitance”. Reference is made to FIG. 2. In FIG. 2, the drive circuitry 112 of the measurement circuitry 105 is configured to generate and apply an electrical stimulus (drive signal) 113 to sequentially stimulate each of an array of transmitter (driven/drive) electrodes, shown as the X electrodes 101 in FIG. 2, that are coupled by virtue of their proximity to an array of receiver electrodes, shown as the Y electrodes 102 in FIG. 2. (It should be appreciated that the Y electrodes 102 may instead be the transmitting electrodes and the X electrodes 101 may instead be the receiving electrodes in other implementations). The resulting electric field 110 is now directly coupled from the transmitter to each of the nearby receiver electrodes. This is in contrast to systems which employ a technique that measure the “self-capacitance” of an electrode. The area local to and centred on the intersection of a transmitter and a receiver electrode is typically referred to as a “node” or “intersection point”. Now, on application or approach of a conductive element such as a human finger, the electric field 110 is partly diverted to the touching object. That is, some of the field couples via the finger through the connected body 118, through free space and back to the measurement circuitry 105. An extra return path to the measurement circuitry 105 is hence established via the body 118 and “free-space”. However, because this extra return path acts to couple the diverted field directly to the measurement circuitry 105, the amount of field coupled to the nearby receiver electrode 102 decreases. This is measured by the measurement circuitry 105 as a decrease in the “mutual-capacitance” between that particular transmitter electrode and receiver electrodes in the vicinity of the touch 109. The measurement circuitry 105 senses this change in capacitance of one or more nodes. For example, if a reduction in capacitive coupling to a given Y-electrode is observed while a given X-electrode is being driven, it may be determined there is a touch in the vicinity of where the given X-electrode and given Y-electrode cross, or intersect, within the sensing area of the sensor element 100. The magnitude of a capacitance change is nominally proportional to the area 120 of the touch (although the change in capacitance does tend to saturate as the touch area increases beyond a certain size to completely cover the nodes directly under the touch) and weakly proportional to the size of the touching body (for reasons as described above). The magnitude of the capacitance change also reduces as the distance between the touch sensor electrodes and the touching object increases.

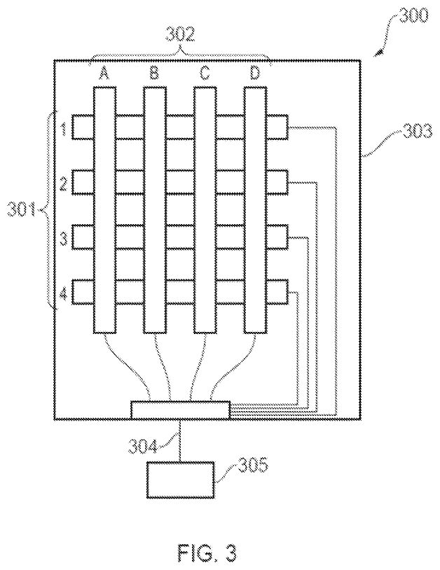

In the described implementation, the electrodes 101, 102 are arranged on an orthogonal grid, with a first set of electrodes (e.g., the transmitter electrodes 101) on one side of a substantially insulating substrate 103 and the other set of electrodes (e.g., the receive electrodes 102) on the opposite side of the substrate 103 and oriented at substantially 90° to the first set. This is also as schematically shown in FIG. 3. In other implementations, the electrodes may be oriented at a different angle (e.g., 30°, 40°, etc.) relative to one another. In addition, it should also be appreciated that it is also possible to provide structures where the grid of electrodes is formed on a single side of the substrate 103 and small conductive bridges are used to allow the two orthogonal sets of electrodes to cross each other without short circuiting. However, these designs are more complex to manufacture and less suitable for transparent sensors. Regardless of the arrangement of the electrodes, broadly speaking, one set of electrodes is used to sense touch position in a first axis that we shall call “X” and the second set to sense the touch position in the second orthogonal axis that we shall call “Y”.

The mutual capacitance measurement technique offers some advantages over other techniques, such as self-capacitance measurement techniques, in that mutual capacitance measurement techniques can identify mutual capacitance changes independently at each of the electrode intersection points. This means that the mutual capacitance technique lends itself to applications which require the detection of multiple touches as inputs to associated apparatuses (such as a PC or other computing device running a software application). However, the mutual capacitance technique is generally not as sensitive to touches as other techniques such as self-capacitance measurement techniques, partly due to the fact that sources of noise have a much more significant impact on the signals received using the mutual capacitance measurement technique. What this means is that it may be more difficult when using mutual capacitance measurement techniques to correctly identify a touch as genuine (i.e., resulting from a user touching the touch sensitive element) as opposed to a source of noise. In order to increase the sensitivity, a greater sample time is required for sampling the signal (i.e., the measured mutual capacitance). This provides a greater signal to noise ratio. However, increasing the sample time to increase the ability of the touch sensor to sense a genuine touch (i.e., improve sensitivity) generally increases the response time of the system (i.e., how quickly the touch-sensitive apparatus responds (outputs an indication that a touch is detected) when an object is first placed on the touch-sensitive present). A balancing of these two considerations is a part of what drives the design of mutual capacitance measurement based touch sensors.

FIG. 3 shows an example touch-sensitive apparatus 301 for the purposes of explaining the issues associated with a mutual capacitance measurement technique described above. The touch-sensitive apparatus 300 includes X-direction electrodes 301, Y-direction electrodes 302, an insulating substrate 303 on which the Y electrodes 302 are arranged on one side and the X-direction electrodes are arranged on the other side, connectors 304 which electrically connect the electrodes 301 and 302 to measurement circuitry 305. Other features which are not directly relevant to the example description are omitted for clarity. The electrodes 301, 302, substrate 303, and conductors 304 may be broadly similar to electrodes 101, 102, substrate 103 and conductors 104 described in conjunction with FIG. 1 above, and a specific description of these features is omitted here. In order to aid explanation, each of the eight electrodes 301 and 302 shown is given an identifier. The four electrodes 301 (those that extend spatially in the X direction) are given the identifiers 1 to 4, while the four electrodes 302 (those that extend spatially in the Y direction) are given the identifiers A to D. The electrodes 301 and 302 in this implementation are orthogonal to one another and spatially intersect at various locations in the X-Y plane (although do not intersect in the Z axis), and these points are herein referred to as intersection points (or sensor nodes). The various intersection points are denoted according to combinations of the identifiers of the corresponding electrodes 301 and 302. For example, the intersection of electrode A and electrode 1 is denoted as intersection point A1, the intersection of electrode B and electrode 2 is denoted as intersection point B2, etc. It should be understood that each of the intersection points corresponds to a position in the X-Y plane of the touch-sensitive element. In other words, the intersection points can be translated into two-dimensional Cartesian coordinates on the surface of the touch-sensitive element.

A first example of obtaining the measurements indicative of the mutual capacitance at each of the intersection points or nodes is now described. Each of the drive electrodes 301 is driven, sequentially, with a drive signal (generated by suitable circuitry such as the drive circuitry 112 above). When considering an example of four drive electrodes 301 as in FIG. 3, the measurement circuitry 305 applies a drive signal to electrode 1 for a first time period, then applies the drive signal to electrode 2 for a second time period once the first time period has elapsed, then applies the drive signal to electrode 3 for a third time period once the second time period has elapsed, and finally applies the drive signal to electrode 4 for a fourth time period once the third time period has elapsed. The first, second, third and fourth time periods are of the same duration, T. When the measurement circuitry 305 is applying the drive signal to one of the electrodes 301, during that time period the measurement circuitry 305 may sequentially couple each receive electrode 302 in turn such that the electric field generated by the transmit electrode is coupled to the measurement circuitry 305 via the corresponding receive electrode 302. At this time, the measurement circuitry 305 obtains a measurement indicative of the mutual capacitance at the corresponding intersection point. For example, when the drive signal is applied to electrode 1, the measurement circuitry sequentially couples to electrode A for a fifth time period, then to electrode B for a sixth time period, then to electrode C for a seventh time period, and finally to electrode D for an eighth time period. The fifth, sixth, seventh and eighth time periods are of the same duration and in this instance are T/4, such that the sum of the fifth, sixth, seventh and eighth time periods is equal to the time duration T. (Note that the fifth to eighth time periods are named as such just for distinction over the first to fourth time periods, and it should be understood from above that the fifth to eighth time periods form the first time period in the example given).

Accordingly, the measurement circuitry 305 is able to obtain signals indicative of the mutual capacitance at the various intersection points. For example, following from above, while the measurement circuitry 305 applies the drive signal to electrode 1, indications of the mutual capacitances at the intersection points A1, B1, C1, and D1 during the fifth to eight time periods can be obtained respectively. The measurement circuitry 305, after time T has elapsed, then applies the drive signal to the next electrode of the transmit electrodes, i.e., electrode 2, and sequentially couples the receive electrodes A to D as described above to obtain values indicative of the mutual capacitance at intersection points A2, B2, C2, and D2 (i.e., over equivalent time periods to the fifth to eighth time periods discussed above). This process is repeated for all drive electrodes of the electrode array to perform a complete “scan” of all the electrode intersection points.

It should be appreciated the described processed may be reversed; that is, each transmit electrode 1 to 4 is sequentially supplied with a signal for a time period of T/4 while one given receive electrode is coupled to the measurement circuitry 305.

Attempts have been made to streamline such a technique, noting above that touch sensitive apparatuses may be designed so as to balance the responsiveness (i.e., the time required to perform a complete scan of the electrode array) with the sensitivity (i.e., the ability to determine whether a sensed touch is genuine). One approach is to simultaneously couple a plurality of receive electrodes 302 to the measurement circuitry 305. In this regard, the measurement circuitry 305 may comprise a number of channels, each channel having suitable circuitry for receiving the signal from a receive electrode 302. Accordingly, rather than coupling individual receive electrodes 302 to the measurement circuitry 305 for discrete time periods (e.g., the fifth, sixth, etc. time periods) while one drive electrode 301 is being driven, a plurality of receive electrodes 305 can be coupled to the measurement circuitry 305 while a drive electrode 301 is being driven. For example, if two receive electrodes (e.g., receive electrodes A and B) are coupled to two separate channels of the measurement circuitry 305, then when drive electrode 1 is being driven, the measurement circuitry 305 may obtain an indication of mutual capacitance at intersection points A1 and B1 simultaneously in the fifth time period, before obtaining an indication of mutual capacitance at intersections points 1C and 1D during a sixth time period when receive electrodes C and D are coupled to the measurement circuitry 305. In this case the seventh and eighth time periods are not required. In this instance, either the first time period can be reduced from T to T/2 with each of the fifth and sixth time periods remaining at T/4, or the first time period remains at T with each of the fifth and sixth time periods increasing from T/4 to T/2. Reducing a time period can help improve the responsiveness of the touch sensitive apparatus, while increasing the time period can help improve the sensitivity (e.g., the signal to noise ratio) of the touch-sensitive apparatus. As above, it should be appreciated that some compromise or balance between the two may is also possible.

For the sake of completeness, it should be noted that the measurement circuitry 305 may use a multiplexer (not shown in FIG. 3) to selectively apply the drive signal to the transmit electrodes 301, and/or a multiplexer to selectively connect the receive electrodes 302 to the measurement circuitry 305. This allows a single drive circuitry and single receive circuitry to be used to make all the measurements, thus decreasing the overall costs of the circuitry. However, in other arrangements, each drive electrode may be coupled to its own drive circuitry which is selectively operated, and each receive electrode may be coupled to its own receive circuitry which is selectively or simultaneously operated. It should be appreciated that a combination of the two approaches may also be used, for example the drive electrodes may be coupled to a multiplexer and driven sequentially, while the receive electrodes are individually coupled to corresponding receive circuitry, or vice versa.

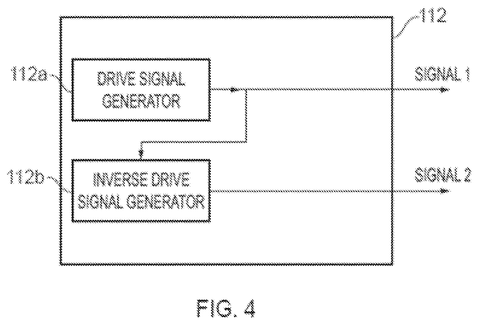

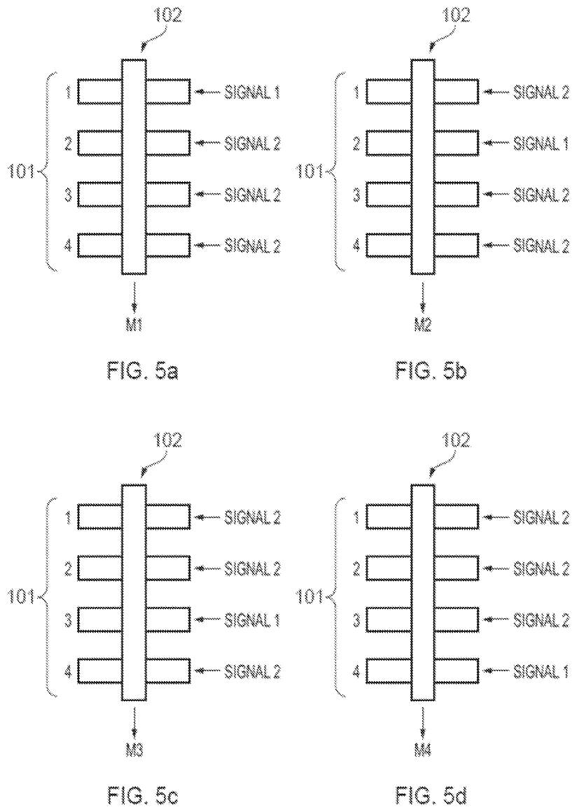

In addition, techniques have been proposed which offer the potential for further improvements in the responsiveness and/or sensitivity of the touch sensitive apparatus. In respect of the example described with FIG. 3, each drive electrode 301 is driven sequentially with a time-varying signal (such as a time-varying voltage signal). Each drive electrode 301 of the electrode array is typically driven with the same time-varying voltage signal and, as such, each drive electrode is driven separately from the other drive electrodes. However, techniques that offer a potential improvement in the sensitivity and/or responsiveness of the touch-sensitive apparatus 1 may be implemented by driving multiple drive electrodes using different drive signals. This will be explained with reference to FIGS. 4 and 5 below.

FIG. 4 is a highly schematic representation of the drive circuitry 112 of FIG. 1 in more detail. The drive circuitry 112 comprises a drive signal generator 112a and an inverse drive signal generator 112b. The drive signal generator 112a is configured to generate a first time-varying voltage signal, and more specifically time-varying voltage signal that follows a sinusoidal variation in time. For convenience, this is referred to as signal 1. Signal 1 varies sinusoidally in accordance with a certain frequency, ω, and has a certain amplitude, A. In other words, signal 1 may be represented mathematically as:

signal 1=+A sin(ωt) (1)

As shown in FIG. 4, signal 1 is input into inverse drive signal generator 112b. The inverse drive signal generator 112b is configured to invert signal 1 to produce a second signal, signal 2. In this instance, signal 2 is the inverse of signal 1. That is, signal 2 is a time-varying voltage signal which varies sinusoidally in accordance with the frequency, ω, and has an amplitude, A, but is 180° out of phase with signal 1. In other words, when signal 1 is positive, signal 2 is negative by an equal but opposite amount. Signal 2 may be represented mathematically as:

signal 2=−A sin(ωt) (2)

Signal 1 and signal 2 are orthogonal to one another. In other implementations, the drive signal generator 112 is configured to provide a plurality of suitable drive signals for driving one or more electrodes of the touch-sensitive apparatus 1, whereby each drive signal is orthogonal to one another.

The inverse drive signal generator 112b may be implemented using any suitable circuitry capable of inverting an input signal. Additionally, while the present implementation shows the inverse drive signal generator 112b receiving signal 1 and inverting signal 1 to produce signal 2, in other implementations, the inverse drive signal generator 112b may comprise similar circuitry to drive signal generator 112a and is controlled to generate an inverse signal to signal 1.

In the touch-sensitive apparatus 1 described in FIG. 1, the measurement circuitry 105, which comprises drive circuitry 112, outputs signal 1 and/or signal 2 to the drive electrodes 101. More specifically, the measurement circuitry 105 is configured drive ones of the drive electrodes 101 using signal 1 and signal 2. FIGS. 5a to 5d exemplify how a group of electrodes are driven in various scenarios using schematic representations of the electrodes 101 and 102 of FIG. 1. Other features of FIG. 1 are omitted from FIGS. 5a to 5d for reasons of clarity. FIGS. 5 a to 5 d illustrate a group of four drive electrodes 101 and a single receive electrode 102. For facilitating explanation, each of the drive electrodes has an identifier 1 to 4 (in a similar manner to as described in relation to FIG. 3).

The measurement circuitry 105 is configured to apply signal 1 and signal 2 to the group of four drive electrodes 101. Initially, the measurement circuitry 105 applies signal 1 to a first transmit electrode (electrode 1) and signal 2 to the second to fourth electrodes (electrodes 2 to 4), as shown in FIG. 5a. The signals 1 and 2 are applied for a certain time period, e.g., T/4, and during this time, the measurement circuitry 105 makes a measurement M1 using receive electrode 102. The measurement M1 is effectively a summation of each of the signals received from the intersection points of the four electrodes with the receive electrode.

After the time T/4 has elapsed, the measurement circuitry 105 is then configured to apply signal 1 to the second transmit electrode (electrode 2) and signal 2 to the first, third and fourth electrodes (electrodes 1, 2, and 3), as shown in FIG. 5b. The signals 1 and 2 are again applied for a certain time period, e.g., T/4, and during this time, the measurement circuitry 105 makes a measurement M2 using receive electrode 102. As above, in the absence of a touch, M2 is effectively a summation of the signals from the four intersection points.

The process is repeated where signal 1 is applied to electrode 3 and then electrode 4, while signal 2 is applied to the remaining electrodes, and measurements M3 and M4 are made using receive electrode, as shown in FIGS. 5c and 5d respectively.

The measurement circuitry 105 outputs measurements M1 to M4 to the processing circuitry 106. The processing circuitry 106 is configured to determine the mutual capacitance for each of the intersection points between electrodes 1 to 4 and receiver electrode 102. In particular, for the receiver electrode 102, processing circuitry 106 is configured to determine the mutual capacitances for the intersection points for electrodes 1 to 4 with receiver electrode 102 using the following equations:

E₁₀₂₋₁=M1−M2−M3−M4 (3)

E₁₀₂₋₂=M2−M1−M3−M4 (4)

E₁₀₂₋₃=M3−M1−M2−M4 (5)

E₁₀₂₋₄=M4−M1−M2−M3 (6)

where E₁₀₂₋ₙ is the measured mutual capacitance for the intersection point between electrode 102 and electrode n of the drive electrodes 101.

When a drive signal is applied to a drive electrode, as mentioned previously, an electric field is generated which couples to the receive electrode(s). The magnitude of the receive signal (i.e., the signal on the receive electrode) is proportional to the magnitude of the drive signal (i.e., the signal applied to the drive electrode). If the magnitude of the drive signal is represented by |A|, the magnitude of the receive signal can be represented by |B|. Each measurement M1 to M4 is therefore effectively a summation of the corresponding coupled drive signal as detected by the receiving electrode. Assuming that both signal 1 and signal 2 when applied to a given transmit electrode couple to the receive electrode in the same way, then measurements M1 to M4 can be mathematically represented as:

M1=+−B1 sin(ωt)+−B2 sin(ωt)+−B3 sin(ωt)+−B4 sin(ωt) (7)

M2=−B1 sin(ωt)++B2 sin(ωt)+−B3 sin(ωt)+−B4 sin(ωt) (8)

M3=−B1 sin(ωt)+−B2 sin(ωt)++B3 sin(ωt)+−B4 sin(ωt) (9)

M4=−B1 sin(ωt)+−B2 sin(ωt)+−B3 sin(ωt)++B4 sin(ωt) (10)

where Bn signifies the amplitude of the coupled signal as received at the receive electrode 102 from drive electrode n.

Note that, although not shown in equations (7) to (10), additional signals (such as a noise signal, e.g., from an external source) may also couple to the receive electrode and thus be present in the measurements M1 to M4.

In the absence of a touch, and assuming that the coupling between each transmit electrode and receive electrode is the same (that is, electrode 1 couples signals 1 and 2 to the receive electrode by the same amount as electrode 2 couples signals 1 and 2, etc.), then B1, B2, B3, and B4 are all equal (for convenience we shall refer to this as B), and effectively each measurement M1, M2, M3 and M4 is equal to −2B sin(ωt). Accordingly, under this assumption, using equations (3) to (6), the signal indicative of the mutual capacitance at each of the intersection points E₁₀₂₋₁, E₁₀₂₋₂, E₁₀₂₋₃, and E₁₀₂₋₄, is equal to 4B sin(ωt). This is a value indicative of the mutual capacitance at the intersection point between the receive electrode 102 and each of the transmit electrodes 1 to 4 in the absence of any touch from a user of the touch-sensitive apparatus. This signal indicative of the mutual capacitance at the given intersection point may be referred to as indicative of the steady state of the mutual capacitance at the respective intersection point. (However, it should again be appreciated that such a steady state signal may vary due to the presence of any additional signals, such as noise, which may themselves manifest as time-varying signals).

When a user touches or otherwise interacts with the touch-sensitive apparatus 1, e.g., by touching the touch-sensitive apparatus 1 at the intersection point between drive electrode 1 and the receive electrode 102, then the coupling of the drive signal 1 or 2 to the corresponding receive electrode is changed (and in particular lowered). In other words, B1 is no longer equal to B. Using equations (3) to (6), and assuming that B2, B3, and B4 are all equal to B in equations (7) to (10), then the signals for the intersection points now read as:

E₁₀₂₋₁=4B1 sin(ωt) (11)

E₁₀₂₋₂=4B sin(ωt) (12)

E₁₀₂₋₃=4B sin(ωt) (13)

E₁₀₂₋₄=4B sin(ωt) (14)

By applying orthogonal drive signals at different discrete time periods to a group of drive electrodes, and combining the obtained measurements (e.g., M1 to M4) in different ways, the processing circuitry 106 is capable to obtaining indications of the mutual capacitances at each of the intersection points.

However, what should be appreciated with the above technique is that, for example, although each measurement M1 to M4 is obtained over a time period of T/4, measurement data regarding the mutual capacitance at each intersection point for a given receive electrode is obtained in each of the measurements M1 to M4. Accordingly, measurement data for each intersection point is actually obtained over the time period T (e.g., in this case four times T/4 corresponding to the four measurements M1 to M4). Thus, effectively the number of samples for a particular intersection point is increased by four in this example relative to the method described in conjunction with FIG. 3, whereby each intersection point in FIG. 3 is sampled for a time period of T/4. The signal to noise ratio is dependent, in part, upon the square root of the number of samples (or, assuming a constant sample rate, the duration over which the measurements are sampled), and thus the processing circuitry 106 is able to obtain measurements having a roughly double signal to noise ratio for a given signal as compared to the mutual capacitance technique described in relation to FIG. 3.

As above, it should be understood that responsiveness and/or sensitivity of the touch-sensitive apparatus 1 may be improved as compared to the measurement technique described in relation to FIG. 3. For a single receive electrode 102, the total time to perform a scan of all drive electrodes (e.g., electrodes 1 to 4) is T (i.e., T/4 times four). This is the same as in the measurement technique described in FIG. 3 above (assuming the time period T is the same in each example), but each measurement is obtained over a time period of T rather than T/4. Accordingly, one could instead increase the responsiveness of the system by setting each time period over which the measurements M1, M2, etc. are obtained to T/16, which subsequently reduces the total time to perform a scan to T/4 while maintaining the same signal-to-noise ratio as with the measurement technique described in FIG. 3.

For completeness, it should be understood that processing circuitry 106 may utilise the signals indicative of the mutual capacitance of each of the intersection points to ascertain whether a touch is detected at any one or more of the intersection points. In this regard, the processing circuitry 106 may determine a change in the magnitude of the signal indicative of the mutual capacitance or the mutual capacitance itself at a given intersection point relative to a reference value. The reference value is indicative of the magnitude of the signal indicative of the mutual capacitance or the mutual capacitance itself obtained at the given intersection point in the absence of any touch. This value may be obtained in advance during a calibration process, either through empirical testing or computer modelling, or is a value that is continually updated during use of the touch-sensitive apparatus 1. When the difference between the reference value and the corresponding measured value exceeds a threshold, this may be interpreted by the processing circuitry 106 as an indication that a touch is detected at the given intersection point (which may correspond to an X-Y position on the touch sensitive surface of the touch-sensitive apparatus 1 as described above). For example, the processing circuitry 106 is configured to determine a change in mutual capacitance by calculating the difference between the measured value of the mutual capacitance at an intersection point and a baseline value of the mutual capacitance for the intersection point in the absence of a touch obtained in advance. That is, the processing circuitry may subtract the value of E₁₀₂₋₁ obtained in equation (11) (or an average thereof) from the value of E₁₀₂₋₁ obtained in the absence of a touch (or an average thereof) and compare the difference to a predefined threshold. If the difference is greater than the predefined threshold, then the processing circuitry 106 may output a signal indicating the presence of a touch on the touch sensitive element. The output signal may either be an indication that a touch is detected, or it may include the location (e.g., X-Y coordinates) of the detected touch on the touch sensitive element.

The above has described a technique for offering potential performance advantages for a touch-sensitive apparatus 1 when used to sense one or more touches on a touch-sensitive apparatus from a user. However, the touch-sensitive apparatus 1 and technique described above is generally incapable of distinguishing between different users who interact with the touch-sensitive apparatus 1. For example, whether a first user or a second user touch the touch-sensitive apparatus 1 at a location broadly corresponding to a given intersection point, the change in the signal indicative of the mutual capacitance or the mutual capacitance itself from the reference value may be largely the same for either user. In some applications, it may be required to distinguish between different users when using the touch-sensitive apparatus 1 as an input device (e.g., so as to allow or restrict certain inputs corresponding to one user or another user). Accordingly, the present inventors have devised a touch-sensitive system capable of differentiating touches originating from different users.

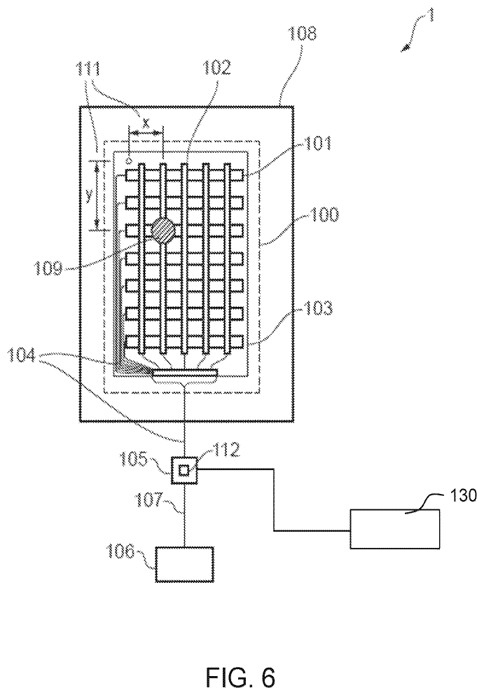

FIG. 6 schematically represents a touch-sensitive system in accordance with the principles of the present disclosure, whereby the touch-sensitive system is configured to allow a touch (or interaction) from a first user to be distinguished from a second user. FIG. 6 shows a touch-sensitive system comprising the touch-sensitive apparatus 1 of FIG. 1 in conjunction with a user identification electrode 130. FIG. 6 will be understood, in part, from FIG. 1 and accordingly like components are described with the same reference signs. A description of these components is omitted here for conciseness, and only the differences will be explained.

As shown in FIG. 6, the touch-sensitive system comprises a user identification electrode 130 which is shown coupled to the measurement circuitry 105 of the touch-sensitive apparatus 1. The user identification electrode 130 is an electrically conductive component which is capable of receiving a drive signal (e.g., drive signal 1 or drive signal 2) from the drive signal generator 112 of the measurement circuitry 105. The user identification electrode 130 may be formed from any suitable electrically conductive material, such as those described above in relation to electrodes 101 and 102 above.

The user identification electrode 130 is provided at a separate location from the sensor element 100/electrode array 101, 102 of the touch-sensitive apparatus 1. That is to say, the user identification electrode 130 is remote from the sensor element 100. Accordingly, the touch-sensitive system comprises a senor element 100 comprising electrodes 101 and electrodes 102 defining a sensing surface at which touches (or objects) are capable of being sensed, in addition to a separate user identification electrode 130 which does not form part of the sensor element 100 and is remote from the sensor element 100. Instead, the user identification electrode 130 is arranged so as to electrically (and more specifically capacitively) couple to a first user of the touch-sensitive system. For example, the user identification electrode 130 may be provided on an object that the first user makes physical contact with (herein referred to as a user object). The user object may be considered fixed, for example such as a seat, whereby the user object rarely moves or is only permitted to move in a particular predetermined manner. By way of example only, the touch-sensitive system may be employed in a vehicle, such as a car, whereby the touch-sensitive apparatus 1 provides an interactive input device for controlling various functionality provided with the vehicle, e.g., provided on a dashboard of the vehicle, and the user identification electrode 130 is provided coupled to a seat of the vehicle, such as a driver's seat or a passenger's seat. Alternatively, the user identification electrode 130 may be provided on or as part of a user object that is not fixed in a particular location or in other words is capable of being more freely moved by a user, e.g., as part of a wearable item such as a watch or a fabric cuff, or as part of an object that the user uses to interact with the touch-sensitive apparatus, such as a stylus. When the user object is not fixed, the movement of the user object may be restricted by the physical connection between the measurement circuitry 105 and the user identification electrode 130 (e.g., the length and/or flexibility of the physical connection).

Regardless of the specifics of the user object, the user identification electrode 130 is arranged such that a drive signal applied thereto is capable of capacitively coupling to the first user. As described above, the measurement circuitry 105 is configured to apply drive signals (e.g., drive signal 1 and/or drive signal 2) to the electrodes of the electrode array 101, 102 but in the touch-sensitive system of FIG. 6 is additionally configured to supply a drive signal (e.g., drive signal 1 or drive signal 2) to the user identification electrode 130. The measurement circuitry 105 may thus comprise any suitable circuitry configured to provide the drive signal at a suitable magnitude for both safely capacitively coupling to the first user and for providing the drive signal at a level sufficient to implement the principles of the present disclosure. The measurement circuitry 105 may therefore be provided with an amplifier or corresponding circuitry capable of amplifying the drive signal 1 or drive signal 2 (or the inversions thereof) to a sufficient level. The precise level/magnitude of the drive signal to be applied to the user identification electrode 130 required may be dependent on any one or more of the properties of the user identification electrode 130 (e.g., size, shape, material), the properties of the user object (e.g., size, shape, material, the relative proximity of the user identification electrode to the user) and/or the intended location of use of the touch-sensitive system (e.g., in a vehicle, cinema, lecture theatre, etc.).

In accordance with the principles of the present disclosure, the measurement circuitry 105 is configured to apply ones of the first and second drive signals (signals 1 and 2) to both the electrode(s) 101 of the electrode array 101, 102 and to the user identification electrode 130. More specifically, using the example described in FIGS. 4 and 5, the user identification electrode 130 essentially replaces one of the group of drive electrodes 101 such that the measurement circuitry 105 drives three drive electrodes 101 and the user identification electrode 130 (instead of driving four drive electrodes 101 as described above).

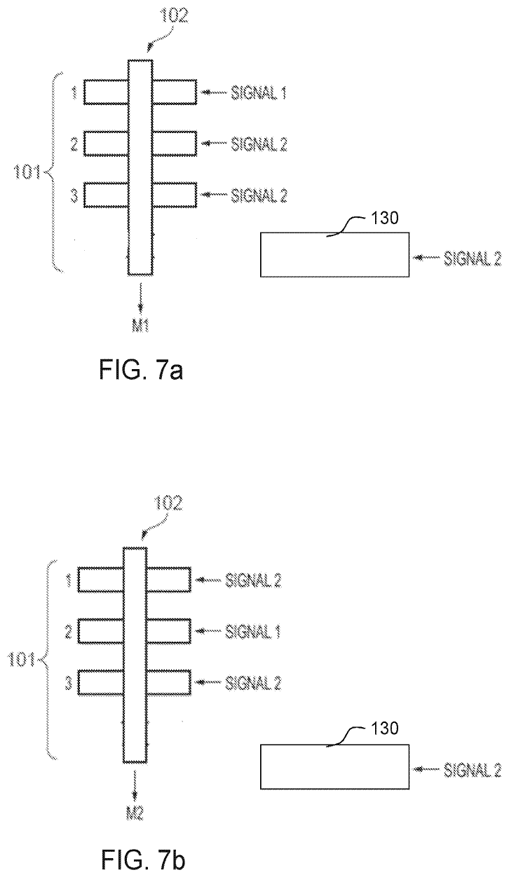

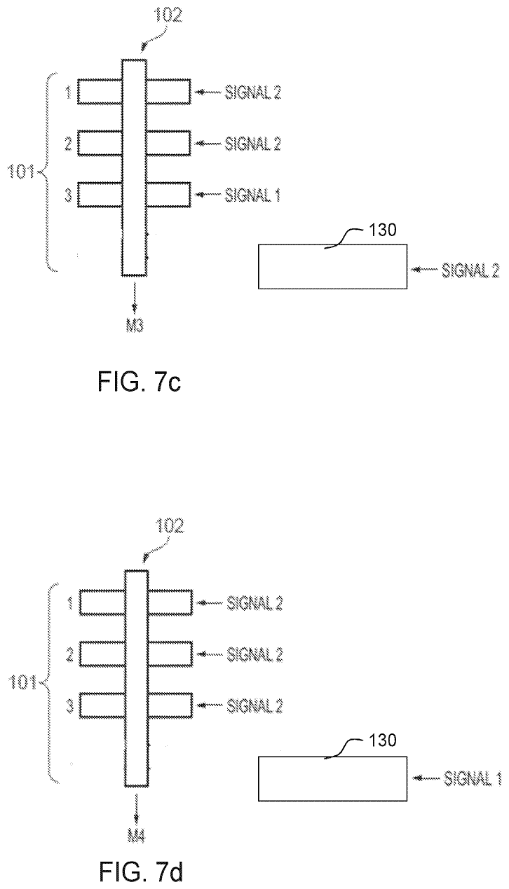

This will be explained below with reference to FIGS. 7a to 7d. FIGS. 7a to 7d schematically exemplify scenarios using representations of the electrodes 101 and 102 of FIG. 1. Other features of FIG. 1 are omitted for reasons of clarity. FIGS. 7a to 7d will be understood from FIGS. 5a to 5d above. However, unlike FIGS. 5a to 5d, FIGS. 7a to 7d illustrate three drive electrodes 101 (labelled 1 to 3 in FIGS. 7a to 7d) in addition to the user identification electrode 130, which is schematically shown separated from the drive electrodes 101 and receive electrode 102 as discussed above.

In accordance with the present disclosure, the measurement circuitry 105 is configured to apply various combinations of one of signal 1 and signal 2 to the group of three transmit electrodes 101 and the user identification electrode 130. However, what is significant with the technique to be described in respect of FIGS. 7a to 7d is that although there are only three intersection points regarding the drive electrodes (e.g., the intersection points 102-1, 102-2 and 102-3), the measurement circuitry 105 proceeds to perform four measurements M1 to M4. In other words, the measurement circuitry 105 is configured to operate in a similar manner as described with respect to FIG. 5, with the exception that the measurement circuitry 105 instead applies one of signal 1 or signal 2 (as the drive signal) to the user identification electrode 130.

FIGS. 7a to 7d will now be explained in more detail. Initially, the measurement circuitry 105 applies signal 1 to a first transmit electrode (electrode 1) and signal 2 to the second and third electrodes (electrodes 2 to 3) and to the user identification electrode 130, as shown in FIG. 7a. The signals 1 and 2 are applied for a certain time period, e.g., T/4, and during this time, the measurement circuitry 105 makes a measurement M1 using receive electrode 102. The measurement M1 is effectively a summation of each of the signals received from the intersection points of the three drive electrodes with the receive electrode 102. It should be appreciated that this scenario is similar to FIG. 5a with the exception that signal 2 is applied to the user identification electrode 130 instead of the fourth electrode of the electrode array.

After the time period, e.g., T/4, has elapsed, the measurement circuitry 105 is then configured to apply signal 1 to the second transmit electrode (electrode 2) and signal 2 to the first and third electrodes (electrodes 1 and 3) and to the user identification electrode 130, as shown in FIG. 7b. The signals 1 and 2 are again applied for a certain time period, e.g., T/4, and during this time, the measurement circuitry 105 makes a measurement M2 using receive electrode 102. As above, M2 is effectively a summation of each of the signals received from the intersection points of the three drive electrodes with the receive electrode 102. It should be appreciated that this scenario is similar to FIG. 5b with the exception that signal 2 is applied to the user identification electrode 130 instead of the fourth electrode of the electrode array.

After the time period, e.g., T/4, has elapsed again, the measurement circuitry 105 is then configured to apply signal 1 to the third transmit electrode (electrode 3) and signal 2 to the first and second electrodes (electrodes 1 and 2) and to the user identification electrode 130, as shown in FIG. 7c. The signals 1 and 2 are again applied for a certain time period, e.g., T/4, and during this time, the measurement circuitry 105 makes a measurement M3 using receive electrode 102. As above, M3 is effectively a summation of each of the signals received from the intersection points of the three drive electrodes with the receive electrode 102. It should be appreciated that this scenario is similar to FIG. 5c with the exception that signal 2 is applied to the user identification electrode 130 instead of the fourth electrode of the electrode array.

Finally, after the time period, e.g., T/4 has elapsed, the measurement circuitry 105 is configured to apply signal 1 to the user identification electrode 130 and signal 2 to the first to third electrodes (electrodes 1 to 3), as shown in FIG. 7d. The signals 1 and 2 are again applied for a certain time period, e.g., T/4, and during this time, the measurement circuitry 105 makes a measurement M4 using receive electrode 102. As above, M4 is effectively a summation of each of the signals received from the intersection points of the three drive electrodes with the receive electrode 102. It should be appreciated that this scenario is similar to FIG. 5d with the exception that signal 1 is applied to the user identification electrode 130 instead of the fourth electrode of the electrode array.

For completeness, it should be understood that the when referring to measurements M1 to M4, these may represent measurements that are obtained at a given point within the respective time periods or, particularly when using a time-varying signal, may represent average or cumulative values obtained over the course of the respective time periods. For instance, it may be appropriate to sample the signal from the receive electrode at a certain sample rate, which is typically smaller than the time period T/4, and the measurements M1 to M4 may represent an average or cumulative value of the obtained samples across the duration of the time period.

The measurement circuitry 105 outputs measurements M1 to M4 to the processing circuitry 106. The processing circuitry 106 is configured to determine the mutual capacitance (or an indication thereof) for each of the intersection points between electrodes 1 to 3 and receiver electrode 102. In addition, and unlike with the technique described in respect of FIG. 5, the processing circuitry 106 is also configured to determine whether a signal originating from the user identification electrode 130 is also present from the measurements M1 to M4. In particular, utilising variations of the equations (3) to (6) above, the processing circuitry 106 is able to determine the mutual capacitance (or an indication thereof) for each of the intersection points between electrodes 1 to 3 and whether a signal originating from the user identification electrode 130 is also present. In particular, the equations may take the form of:

E₁₀₂₋₁=M1−M2−M3−M4 (15)

E₁₀₂₋₂=M2−M1−M3−M4 (16)

E₁₀₂₋₃=M3−M1−M2−M4 (17)

E₁₃₀=M4−M1−M2−M3 (18)

where E₁₀₂₋ₙ is the mutual capacitance (or an indication thereof) for the intersection point between electrode 102 and electrode n of the drive electrodes 101 (and substantially mirror equations (3) to (5)), and E₁₃₀ is indicative of a signal originating from the user identification electrode 130 (and substantially mirrors equation (6)).

The way in which the processing circuitry 106 is capable of determining whether a signal originating from the user identification electrode 130 is perhaps more easily understood by considering the equations representing measurements M1 to M4. As described above, when a drive signal (either drive signal 1 or drive signal 2) is applied to any one of the drive electrodes 1 to 3, that signal couples to the receive electrode 102 and provides a signal which at least has a component corresponding to the drive signal. As noted above, this can be represented mathematically as B1 sin(ωt) for the coupling between electrode 1 and the receive electrode 102, B2 sin(ωt) for the coupling between electrode 2 and the receive electrode 102, and B3 sin(ωt) for the coupling between electrode 3 and the receive electrode 102. When a drive signal is applied to the user identification electrode 130, the drive signal only couples to the receive electrode 102 when a user (who is capacitively coupled to the user identification electrode 130) when the user or an object they are holding, such as a stylus, is brought into proximity of the receive electrode 102. On the assumption that this occurs, the drive signal applied to the user identification electrode 130 couples to the receive electrode, and can be represented mathematically as C sin(ωt). With this information, equations (7) to (10) can be re-written as follows:

M1=+B1 sin(ωt)+−B2 sin(ωt)+−B3 sin(ωt)+−C sin(ωt) (19)

M2=−B1 sin(ωt)++B2 sin(ωt)+−B3 sin(ωt)+−C sin(ωt) (20)

M3=−B1 sin(ωt)+−B2 sin(ωt)++B3 sin(ωt)+−C sin(ωt) (21)

M4=−B1 sin(ωt)+−B2 sin(ωt)+−B3 sin(ωt)++C sin(ωt) (22)

where, as before, Bn signifies the amplitude of the coupled signal as received at the receive electrode 102 from drive electrode n, C signifies the amplitude of the coupled signal as received at the receive electrode 102 from the user identification electrode 130.

Putting equations (19) to (22) into equations (15) to (18) above, it should be appreciated that each of E₁₀₂₋₁ to E₁₀₂₋₃ result in respective equations for the mutual capacitance (or indications thereof) at each of the intersection points 102-1 to 102-3. In the absence of a touch at any of the intersections of the drive electrodes and receive electrodes 102, we may assume that B1=B2=B3 and C=0. In this case, each of E₁₀₂₋₁ to E₁₀₂₋₃ can be represented as:

E₁₀₂₋₁=E₁₀₂₋₂=E₁₀₂₋₃=4B sin(ωt) (23)

Additionally, because C=0, equation (18) for E₁₃₀ is also equal to zero.

If we assume a touch at any of the intersection points is present (for example, we will assume at the intersection point 102-1) and that touch is from a user coupled to the user interaction electrode 130, then the equations for E102-1 to E102-3 and E130 are represented as follows:

E₁₀₂₋₁=4B1 sin(ωt) (24)

E₁₀₂₋₂=E₁₀₂₋₃=4B sin(ωt) (25)

E₁₃₀=4C sin(ωt) (26)

where B1 is the amplitude of the signal capacitively coupled between the drive electrode 1 and the receive electrode 102 as influenced by the user's touch, and C is non-zero owing to the fact that the drive signal applied to the user identification electrode 130 is capacitively coupled to the receive electrode 102 via the user's touch.

As described above, the processing circuitry 106 is able to determine whether a touch is present at any one of the intersections between drive electrodes 1 to 3 and receive electrode 102 by comparing the magnitudes of the signals, E₁₀₂₋₁ to E₁₀₂₋₃, to previously obtained reference values (which may be the magnitudes of the signals E₁₀₂₋₁ to E₁₀₂₋₃ obtained in the absence of a touch) in a substantially similar manner to as described with respect to FIG. 5. For example, when the difference in magnitudes of E₁₀₂₋₁ of equation (23) and of E₁₀₂₋₁ in equation (24) exceeds a threshold, the processing circuitry 106 may recognise that this is indicative of a touch and perform the necessary action.

However, in accordance with the principles of the present disclosure, the processing circuity 106 is able to identify whether a detected touch (or object) at the sensing surface of the touch-sensitive apparatus 1 is likely to originate from (or result from) a user capacitively coupled to the user identification electrode 130, by utilising the measurements M1 to M4 obtained in each of the corresponding discrete time periods. When the value E₁₃₀ is non-zero, this indicates that the user capacitively coupled to the user identification electrode 130 touches the sensor element 100 at a location corresponding to the receive electrode 102. When a user that is capacitively coupled to the user identification electrode 130 touches the sensor element 100, then the drive signal that is essentially applied to the user via the user identification electrode 130 is coupled to the corresponding receive electrode 102 that is in proximity to the user's touch. Based on identifying the presence of a detected touch, e.g., at E₁₀₂₋₁ as discussed above, if the processing circuitry 106 also determines that the value E₁₃₀ is not equal to zero (i.e., that the user coupled to the user identification electrode 130 interacts with the sensor element 100), then the processing circuitry 106 is configured to determine that it is likely that the detected touch originates or results from the user coupled to the user identification electrode 130.

It should also be appreciated that the processing circuitry 106 is able to identify when a user other than the user capacitively coupled to the user identification electrode 130 touches the sensor element 100. For example, if the user capacitively coupled to the user identification electrode 130 does not touch the sensor element 100, then equation (26) is equal to zero. However, assuming there is nevertheless a touch at the sensor element 100, e.g., corresponding to the intersection point 102-1, then equations (24) and (25) still hold true. In this case, the processing circuitry 106 is able to determine that the touch at intersection point 102-1 likely did not originate from the user capacitively coupled to the user identification electrode 130 due to the absence of any drive signal from the user identification electrode 130 coupled to the receive electrode 102, and therefore the touch likely originated from another user.

Accordingly, based on determining whether a detected touch originates from a user coupled to the user identification electrode 130, any system that employs the touch-sensitive system as an input mechanism is capable of distinguishing between a user coupled to the user identification electrode 130 or a user that is not, and subsequently perform different actions.

Moreover, it should be understood that the abovementioned techniques offer certain advantages. Firstly, by utilising the approaches discussed in FIGS. 5a to 5d and 7a to 7d, improved performance characteristics of the touch-sensitive apparatus 1 can be realised, e.g., the responsiveness and/or sensitivity, as described above. Even when sacrificing one measurement per group of drive electrodes in respect of detecting the presence or absence of a touch on the sensor element 100, the above described techniques offer relatively comparable performance. For example, using the techniques of FIG. 5a to 5d, the average time required per intersection point to make a measurement is T/4. According to the technique of FIG. 7a to 7d, this average time increases to T/3 per intersection point (that is, it takes a period of T to acquire the four measurements M1 to M4 but there are only three intersection points that are being measured in this instance). This results in an increased total time of around 33% to perform the necessary measurements.

Additionally, it should also be understood that a more accurate determination as to whether a user coupled to the user identification electrode 130 touches the touch-sensitive apparatus 1 can be made. This is because any signals associated with the presence of a user's touch from a user coupled to the user identification electrode 130 are obtained at the same time as obtaining signals indicative of a user's touch on the touch-sensitive apparatus (i.e., at the same time as measuring the capacitance changes at intersection points 102-1 to 102-3). Accordingly, the confidence in the origin of the detected touch can be considered to be relatively high.

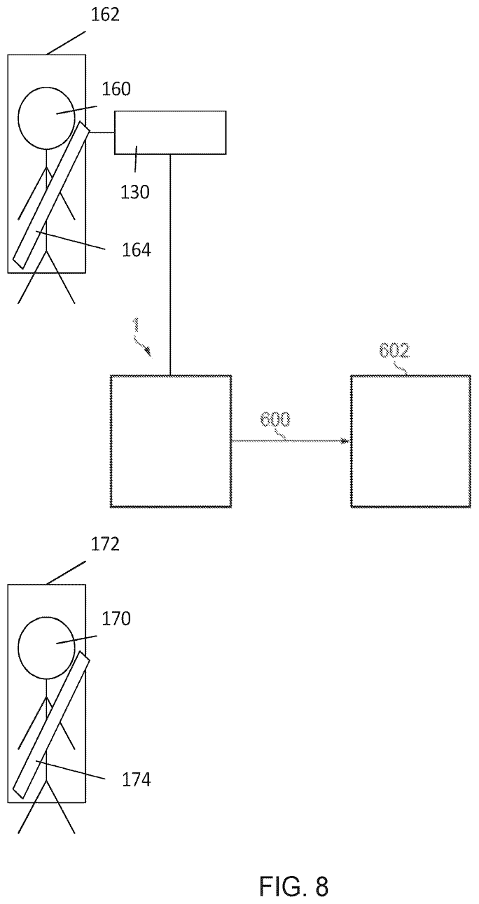

FIG. 8 is a highly schematic diagram showing the touch sensitive system (including the touch sensitive apparatus 1 and user identification electrode 130) coupled to a host apparatus 602 (otherwise known as a host system). The host apparatus 602 utilises the touch sensitive system as an input mechanism, such that one or more user's may interact with the host apparatus 602 via the input mechanism. The host apparatus 602 generally comprises a computer processor which is capable of running a software application, and may also comprise a display element, such as an LCD screen or the like. In some implementations, the touch sensitive apparatus 1 is integrally formed with the host apparatus 602, whereas in other implementations the touch sensitive apparatus 1 is able to be coupled to the associated apparatus 602 e.g., via electrical cabling. As described above, in some instances the substrate 103 and cover 108 of the touch sensitive apparatus 1 are transparent and a display element is placed behind the substrate 103 and cover 108.

By way of example only, FIG. 8 shows the touch-sensitive system and host apparatus 602 implemented in a vehicle, such as a car. It should be appreciated that this is a non-limiting example, and the touch-sensitive system and host apparatus 602 may be utilised in different applications. In the context of a vehicle, the host apparatus 602 may be or comprise an on-board computer or the like which may be responsible for controlling one or more functions provided in the vehicle, while the touch-sensitive apparatus 1 may form part of an interactive dashboard/console arranged to display certain information through an associated display (such as a display placed behind the substrate 103 and cover 108 of the touch sensitive apparatus 1). By way of example, the host apparatus 602 may be configured to provide satellite navigation functionality, whereby the display is configured to display a dynamic map and the one or more users are able to interact with the satellite navigation function via the touch-sensitive apparatus 1.

FIG. 8 also shows two users, the first user 160, which is the driver of the vehicle in this example, and the second user 170, which is the passenger of the vehicle in this example. Each of the first and second users 160, 170 is shown seated in seats 162, 172 and secured via respective safety belts 164, 174. Additionally, it can be seen that user identification electrode 130 is provided so as to couple to the first user 160, specifically via the safety belt 164 which may be provided in contact with the first user 160. In this example, the safety belt 164 is formed of or comprises an electrically conductive element (for example, the safety belt 164 may be formed of a fabric, and may comprise one or more conductive fibres, e.g., such as a metal, woven into or otherwise forming the fabric). In this way, the drive signal applied to the user identification electrode 130 couples to the conductive safety belt 164 (which may, in effect, function as the user identification electrode 130) and allow the drive signal to capacitively couple to the first user 160. It should be appreciated that this is merely an example of how the user identification electrode 130 may be arranged in the vehicle, and other possible locations and arrangements, such as coupling the user identification electrode 130 to seat 162 directly, are within the scope of the present disclosure.

When a touch at the sensor element 100 is detected, as described above, the processing circuitry 106 outputs a signal 600 indicating the presence of a touch to the processing circuitry of the host apparatus 602 (not shown). In accordance with the present disclosure, the signal 600 indicates firstly that a touch has been detected, and secondly whether the touch originates (results) from the first user 160 interacting with the touch-sensitive apparatus 1 or not. In some implementations, the signal 600 also indicates a position of the touch on the sensor element 100, for example as X, Y coordinates (corresponding to one of the intersection points). The processing circuitry of the host apparatus 602 may process the signal 600 in accordance with the application being run on the host apparatus 602. In the example described above, this may include interacting with the satellite navigation, e.g., programming a destination, selecting a certain route, changing a view, etc. Based on the fact that the signal 600 output from the processing circuitry 106 indicates whether the detected touch originates from the first user 160 or not, the host apparatus 602 is able to process signals 600 differently based on whether the touch originates from the first user 160. For example, when the vehicle is in motion, the processing circuitry of the host apparatus 602 may be configured to ignore inputs received by the first user 160 (the driver of the vehicle), thereby promoting safer behaviour by requiring the driver to bring the vehicle to a stop before being able to program the satellite navigation. Alternatively, some functions may only be available to the first user 160, e.g., such as switching on headlights or fog lights via an interacting touch-sensitive button displayed on the display screen of the touch-sensitive apparatus 1, for example.

The above examples represent only some potential uses of the present disclosure, and other uses are envisaged based on the application at hand.

The abovementioned technique has been described in FIGS. 7a to 7d in the context of an electrode array 101, 102 comprising a single receive electrode 102; however, it should be appreciated that the principles described above may be applicable to electrode arrays having multiple receive electrodes 102. As described above, in the case of multiple receive electrodes 102, the measurement circuitry 105 may be configured to, using a multiplexer or the like, sequentially couple to each of the receive electrodes 102 (after measurements have been obtained from the corresponding drive electrodes 101) or to couple to each of the receive electrodes 102 in parallel, where each receive electrode 102 is coupled to a separate measurement channel of the measurement circuitry 105. It should also be appreciated that combinations of such arrangements may also be present, e.g., sequentially coupling groups of receive electrodes 102.

The abovementioned technique has been described in FIGS. 7a to 7d in the context of an electrode array 101, 102 comprising three drive electrodes 101; however, it should be appreciated that the principles described above may be applicable to electrode arrays having different total numbers of drive electrodes 101. In such cases, the principles of the present disclosure may be applied in a number of ways.

In the example shown in FIGS. 7a to 7d, there are three drive electrodes 1 to 3, with each of these drive electrodes being driven at any one time with a drive signal (either drive signal 1 or drive signal 2). When there is a greater number of drive electrodes, for example six drive electrodes, the technique described above may be applied sequentially to different groups of three drive electrodes. For instance, measurements M1 to M4 may be made over a time period of time T for electrodes 1 to 3, as described above, and then a second set of measurements, e.g., M5 to M8, may be made over a subsequent period of time T for electrodes 4 to 6. The user identification electrode 130 in this case is driven with the relevant drive signal over both time periods. This may be repeated for any number of drive electrodes constituting the electrode array 101, 102. When the number of drive electrodes 101 is not divisible by three, then any remaining drive electrodes may be encompassed in multiple groups of three drive electrodes. For instance, when there are five drive electrodes, a group of three drive electrodes (e.g., electrodes 1 to 3) may be driven using the patterns of signals according to FIGS. 7a to 7d, to obtain measurements M1 to M4, followed by driving a second group of electrodes (drive electrodes 3 to 5) to obtain measurements M5 to M8. That is, the measurement circuitry may include certain drive electrode(s), in this case electrode 3, in multiple groups of electrodes. In this case, two measurements would be made for the intersection point E₁₀₂₋₃, although one of these measurements may be disregarded.

FIGS. 7a to 7d describe the sensing technique in respect of a group of three drive electrodes, electrodes 1 to 3, and a user identification electrode 130. In this example, the measurement circuitry is configured to apply combinations of the drive signals over a total of four discrete time periods, whereby each combination of the drive signals in each time period is different. The number of discrete time periods, and therefore the number of corresponding different combinations of drive signals applied, is equal to the total number of electrodes that are being driven (that is, the total number of drive electrodes 101 of the electrode array that are being driven plus the user identification electrode 130). However, it should be understood that the technique described above can be applied to a different total number of electrodes that are being driven at any one time. For example, the technique may be applied to a total number of electrodes that are being driven at any one time of 2, 4, 8, 12, 16, 20, 24, 28, 32, etc. Suitable adaptation of the equations (15) to (22) can be made to account for the different total numbers of electrodes being driven at any one time, which will depend in part upon how the drive signals are applied to each of the electrodes (the drive electrodes and user identification electrodes) in each of the discrete time periods.

Broadly speaking, in the context of the present disclosure, if the number of drive electrodes in a given group of drive electrodes is N, then the number of drive electrodes in a given group of drive electrodes, N, plus the number of user identification electrodes, M, should be equally to one of 2, 4, 8, 12, 16, 20, 24, 28, 32, etc. In the example of FIG. 7 a to 7d, N is equal to three and M is equal to one, so N plus M is equal to 4. It should also be appreciated that the number of measurements performed (and therefore the number of discrete time periods) is also equal to M plus N, and thus by virtue of the above limitation, is also equal to one of 2, 4, 8, 12, 16, 20, 24, 28, 32, etc. By way of example, when the number of drive electrodes in a group, N, is equal to seven and the number of user identification electrodes M is equal to one, N plus M is equal to 8. In this case, eight separate measurements across eight discrete time periods are performed, and each of the measurements in each of the discrete time periods is used in the determination of whether a touch is present and/or whether that touch originates from a user coupled to the user identification electrode 130. Put another way, the number of discrete time periods (or measurements performed) is greater than the number of drive electrodes in a group, N. When there is a single user identification electrode 130 present, i.e., M is equal to one, then the number of discrete time periods (or measurements performed) is greater than the number of drive electrodes in a group, N, by one.

By way of example, we consider the situation where N is equal to one and M is equal to one; that is, where there is a single drive electrode constituting the group of N drive electrodes, and a single user identification electrode 130. Taking this example of a single drive electrode, e.g., electrode 1 of FIG. 7a, and a single receive electrode 102, the measurement circuitry 105 is configured to apply signal 1 to electrode 1 for a first time period, and signal 2 to electrode 1 for a second time period. The measurement circuitry 105 is also configured to apply signal 1 to the user identification electrode 130 for the first and second time periods. The mutual capacitance at the intersection points between electrode 1 and receiver electrode 102, E₁₀₂₋₁ and an indication of a signal originating from the user identification electrode 130, E₁₃₀, may be obtained as follows:

E₁₀₂₋₁=M1−M2 (27)

E₁₃₀=M1+M2 (28)

In this example, the measurements M1 and M2 can be represented as:

M1=+B1 sin(ωt)+C sin(ωt) (29)

M2=−B1 sin(ωt)+C sin(ωt) (30)

Accordingly, the values for E₁₀₂₋₁ and E₁₃₀ can be represented as follows:

E₁₀₂₋₁=2B1 sin(ωt) (31)

E₁₃₀=2C sin(ωt) (32)

Hence, it can be seen that similar principles as described above apply even in the case of a single drive electrode 101 and a single user identification electrode 130. Note that, as with the example described in the context of FIGS. 7a and 7b, the way in which the signals (drive signals 1 and 2) are applied in the respective time periods is determined in accordance with a suitable mathematical combination of the respective measurements M1 and M2 that essentially isolate the components corresponding to the respective intersection points and user identification electrodes. Suitable adaptations, as noted above, are required when the described techniques are applied to a total number of electrodes (that is the drive electrodes and the user identification electrodes) that are being driven at any one time of 8, 12, 16, 20, 24, 28, 32, etc. However, broadly speaking, it should be noted that the drive signal applied to at least one drive electrode or the user identification electrode 130 in a first time period of the plurality of discrete time periods (for obtaining the measurements, e.g., M1 to M4) is different to the drive signal applied to the at least one drive electrode or the user identification electrode 130 in a second time period of the plurality of discrete time periods. More particularly, for each of the plurality of discrete time periods, the relevant circuitry is configured to apply different combinations of one of signal 1 or signal 2 to each of the set of N electrodes and the user identification electrode. For instance, the combinations of the drive signals applied to electrodes 1 to 3 and user identification electrode 130 in each of FIGS. 7a to 7d are different.

Generally speaking, the control circuitry (i.e., the measurement circuitry 105 and processing circuitry 106) of the touch sensitive system is configured to identify a set of N (drive) electrodes of the sensing element 100, where N is an integer greater than or equal to one. The control circuitry is configured to apply one of the first drive signal (signal 1) or second drive signal (signal 2) to each of the set of N (drive) electrodes and also to the user identification electrode 130 over a plurality of discrete time periods. In two different discrete time periods, the drive signal applied to a given one of the N set of electrodes or to the user identification electrode is different (i.e., signal 1 is applied in the first time period, signal 2 is applied in the second time period). The control circuitry is configured to obtain a measurement from the sensing element 100 (e.g., the receive electrode 102 of the sensing element 100) in each of the plurality of discrete time periods. Further, the control circuitry is configured to determine whether a detected touch (or object, e.g., held by a user) at the sensing surface of the sensing element 100 results from a user capacitively coupled to the user identification electrode 130. This determination is based on the obtained measurements from the sensing element 100 in each of the plurality of discrete time periods.

As described above, the control circuitry is configured to combine the measurements obtained in each of the discrete time periods (e.g., through addition and subtraction) to provide a resultant signal being indicative of the capacitive coupling between the sensing element 100 and the user identification electrode 130, given above as E₁₃₀. Equations (18) and (28) show two examples of how these measurements may be combined, for systems implementing a set of N electrodes of N is equal to three and N is equal to one, respectively, although it should be appreciated that different combinations may be required for N being equal to a different number. When a user capacitively coupled to the user identification electrode 130 interacts with the sensing surface of the sensing element 100, the resultant signal (i.e., E₁₃₀) changes. As noted above, the signal (or resultant signal) is dependent on the capacitive coupling between the user/user identification electrode 130 and the electrode array 101, 102, and may either be a direct measure of the capacitance or an indication of the capacitance.

It should also be appreciated that, for example, the value E₁₃₀ of equation (18) or (28) may not necessarily be zero in the event that a user coupled to the user identification electrode 130 does not interact with the touch-sensitive apparatus 1. In particular, there may be some background capacitance that couples to the receive electrode 102, for example, resulting from any external noise sources, and thus a non-zero value for the resultant signal (i.e., the signal indicative of whether a user coupled to the user identification electrode 130 interacts with the sensor element, i.e., E₁₃₀). Accordingly, it may be necessary for the processing circuitry 106 to apply a threshold for more accurately determining whether the signal indicative of whether a user coupled to the user identification electrode 130 interacts with the sensor element, i.e., E₁₃₀, genuinely results from the user interacting with the sensor element 100 (i.e., when the value E₁₃₀ is equal to or greater than the threshold). This may help to ensure that the processing circuitry 106 does not incorrectly attribute a source of external noise with the drive signal applied via the user identification electrode 130. The threshold may be suitably set based on empirical testing or computer modelling.

In terms of detecting a touch at the sensing surface by the control circuitry, as described above, this is based on the obtained measurements from the sensing element 100 in each of the plurality of discrete time periods. More particularly, the control circuitry determines one or more resultant signals (e.g., E₁₀₂₋₁, E₁₀₂₋₂, etc.) indicative of a capacitance associated with the set of N (drive) electrodes based on combinations of the measurements obtained in each of the discrete time periods. The control circuitry determines whether a touch or object is detected at the sensing surface based on whether the one or more resultant signals surpass a threshold value. The threshold value may be a fixed value or, as described above, a reference value set based on a resultant signal obtained in the absence of a touch or object at the sensing surface (either through a calibration process or by measurements obtained during use of the touch-sensitive apparatus 1).

Depending upon the specifics of a given electrode array, in particular the number of drive electrodes, different approaches may be taken in order to scan the complete electrode array. On the one hand, if the total number of drive electrodes is say 15, the number of drive electrodes in a group, N, may be set to 15 with M being set to one (i.e., one user identification electrode). On the other hand, the number of drive electrodes in a group, N, may be set to three with the total number of drive electrodes being divided into five groups of three (in other words with the technique of FIGS. 7a to 7d being applied five separate times to each of the five groups of three drive electrodes). In addition, it should be understood that various combinations may be applied, e.g., a total of 62 drive electrodes may be split into two groups of 31 drive electrodes (i.e., N is equal to 31).

Following from the above, it should be appreciated that the principles of the present disclosure may also apply to situations where there is more than one user identification electrode 130. For example, a user identification electrode 130 may be provided in conjunction with the first user 160 as described above, and a separate user identification electrode 130 may be provided in conjunction with the second user 170. In this case, M is equal to two, and therefore the total number of drive electrodes, N, may be set to 2, 6, 10, 14, etc. The principles still apply as described above, however where one equation may have represented an intersection point with one of the drive electrodes, that equation now represents the user interaction electrode 130 of the second user. For example, in a system where N is equal to two and M is equal to two, equations (19) to (22) may be altered by replacing B3 sin(ωt) with D sin(ωt), where D is the amplitude of the drive signal coupled to the receive electrode via the second user identification electrode. In this case, the value for E₁₀₂₋₃ (of equation 17) instead now is indicative of whether there is any interaction resulting from the second user 170 with the touch-sensitive apparatus 1. This may be extended to any number of user identification electrodes, M, provided N plus M is equal to one of 2, 4, 8, 12, 16, 20, 24, 28, 32, etc. as described above.

As noted above, when a user coupled to the user identification electrode 130 interacts with the sensor element 100, the drive signal applied to the user identification electrode 130 couples to the corresponding receive electrode 102 of the electrode array 101, 102. When there is a single touch detected from an intersection point between a corresponding drive electrode 101 and the given receive electrode 102, then the control circuitry/processing circuitry 106 is capable of associating the presence of the drive signal from the user identification electrode 130 with the detected touch. However, when there are two (or more) touches detected at intersection points along the given receive electrode 102, the processing circuitry 106 is unable to determine which of the two (or more touches) results from the user coupled to the user identification electrode 130. For example, with reference to FIG. 7a to 7d, if touches are detected at the intersection points 102-1 and 102-3, and the signal indicative of a signal originating from the user identification electrode 130 of the user identification electrode, E₁₃₀, is non-zero, the processing circuitry 106 cannot determine which of the touches at the intersection points 102-1 or 102-3 originated from a user that was not coupled to the user identification electrode 130.

In such cases, the touch-sensitive system may further comprise a touch tracking module (for example, implemented as part of the processing circuitry 106, or as a separate component). The touch tracking module is configured to monitor detected touches over time. For example, assuming a first touch is detected at an X, Y position (0, 0) at a time t1, and a second touch is detected at an X, Y position (1, 0) at a time t2, assuming that the change in position at times t1 and t2 (i.e., ΔX, ΔY) is within a certain predetermined amount and the difference in time between times t1 and t2 (Δt) is within a certain predetermined amount, then the tracking module is configured to associate the first touch with the second touch. That is to say, the tracking module assumes the touches detected at times t1 and t2 correspond to a single touch, in this case that is “dragged” or “slid” across the sensing surface. This may also be the case if there is no change in position (i.e., the first touch at time t1 is at 0, 0, and the second touch at time t2 is also at 0, 0), signifying a user applying a touch for a longer period of time. In this regard, the change in position (i.e., ΔX, ΔY) and the difference in time (Δt) are set to an appropriate level depending on a change in position that may reasonably be expected occur for a given touch (e.g., ΔX, ΔY may be set to 5 mm for a Δt of 0.1 ms).

Accordingly, the touch tracking module is capable of associating a series of detected touches over time to a common touch or interaction of the user with the sensor element 100. It should also be understood that in practical implementations, the processing circuitry 106 may require that any given detected touch is present in at least two (or more) consecutive scans of the electrode array 101, 102 in order to consider the touch as properly detected (i.e., not resulting from a noise fluctuation or the like). For an initial touch, once the processing circuitry 106 determines there is a touch, that touch may be essentially given an identifier and any touches identified in subsequent scans that meet the above criteria are associated with the identifier.

In the context of the present disclosure, the touch tracking module is also configured to associate an identifier or flag in respect of a touch that is considered to be associated with a touch provided by a user coupled to the user identification electrode 130. In other words, for the detected touch, if the processing circuitry 106 also identifies the presence of a signal from the user identification electrode 130, i.e., E₁₃₀ is non-zero, the detected touch is associated with a flag signifying the touch results from the user coupled to the user identification electrode 130. Conversely, it should be appreciated that a touch originating from a user who is not coupled to the user identification electrode 130 is subsequently not provided with this flag.

As noted above, when two (or more) touches are detected at intersections points corresponding to a single receive electrode 102, the touch tracking module can be used to help distinguish which of the two (or more) touches originated from a user coupled to the user identification electrode 130 or another user, assuming that there is a signal present from the user identification electrode 130 on the receive electrode 102. Provided that both touches are not first identified at a position corresponding to the receive electrode 102, then the touch tracking module can be used to differentiate between the two or more touches.

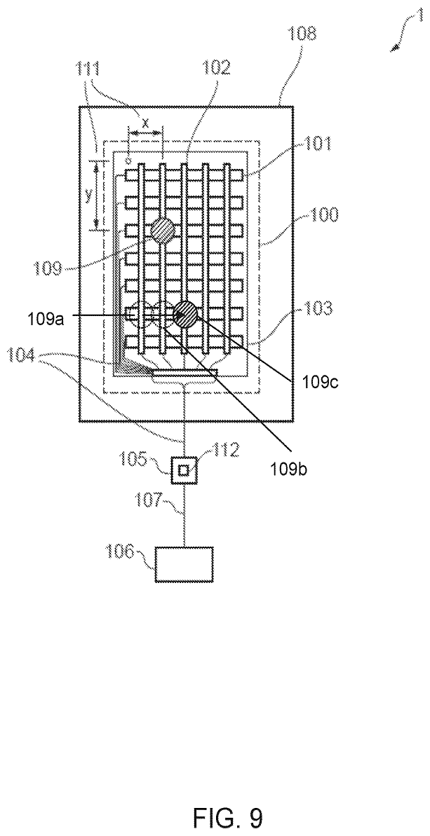

FIG. 9 is a reproduction of FIG. 1 but additionally includes a second touch (represented by reference signs 109a to 109c) for describing the principles of the present disclosure, as will be explained below. FIG. 9 will be understood from FIG. 1 and a detailed discussion of the features of FIG. 9 is not presented here.

Assuming a first user coupled to the user identification electrode 130 touches the sensor element 100 at a first position, i.e., touch 109 in FIG. 9, and holds their touch at that position, the receive electrode 102 underlying that position receives the signal from the user identification electrode 130. Assuming the receive electrode 102 runs top to bottom of the sensor element 100 (e.g., as in FIG. 9), a second user who is not coupled to the user identification electrode 130 touches initially at a position corresponding to a receive electrode that is to the left of the receive electrode underlying the touch from the first user, i.e., at a position 109a shown in FIG. 9. The touch tracking module associates the first touch 109 with a first identifier and/or a flag signifying the touch is received from a user coupled to the user identification electrode 130, and associates the second touch 109a with a second identifier.

Now we assume the second user drags their finger across the sensor element 100 to the right, as shown by the touches indicated at 109b and 109c in FIG. 9, and subsequently across the receive electrode 102 underlying the first user's touch 109. Assuming the abovementioned criteria are met, the touch tracking module is capable of identifying that the touch at position 109b can be associated with the touch at position 109a (i.e., they can be associated with the same identifier) and equally that the touch at position 109c can be associated with the touch at position 109b, and hence also the touch at position at 109a (i.e., all three touches can be associated with the same identifier). Even though it is not possible for the processing circuitry 106 to determine whether the touch 109 or touch 109b corresponds to a touch from the user coupled to the user identification electrode 130 using the techniques as described in relation to FIGS. 7a to 7d alone, based on the additional information received from the touch tracking module, the processing circuitry 106 is capable of differentiating between the two touches 109 and 109b and identifying which of these touches originates from which user (and in particular which touch originates from the user coupled to the user identification electrode 130).

Hence, by implementing a touch tracking module capable of tracking touch data over time and associating touches in different time frames with a common identifier, the processing circuitry 106 is capable of using the additional data relating to the tracking of touches to help distinguish between two (or more) detected touches that detected at in conjunction with the detection of the signal from the user identification electrode 130.

Hence, broadly speaking, the touch-sensitive system of the present disclosure comprises a touch tracking module (which may be part of the control circuitry). The touch tracking module is configured to associate touches detected at a plurality of different times with a common identifier signifying that those touches detected at the plurality of different times correspond to a common touch applied by a user of the touch-sensitive system. The association of a touch with another touch is based on certain criteria relating to the change in position and the difference in time (at which a touch is detected) between the two touches, and provided the criteria are met, the two touches are associated with one another.

The control circuitry, when determining whether a detected touch or object at the sensing surface results from a user capacitively coupled to the user identification electrode, is further arranged so as to use the information from the touch tracking module. In particular, the control circuitry is configured, for a given touch, to identify whether a detected touch is associated with a common identifier and, if the detected touch is associated with a common identifier, the control circuitry determines that the detected touch likely results from the same user that made the other touch(es) associated with the common identifier. In some implementations, the touch tracking module is configured to associate a common identifier with a flag indicative of a touch or a plurality of touches originating from a user capacitively coupled to the user identification electrode 130. In particular, the touch tracking module is configured to associate the flag with the common identifier if the earliest touch in time of the touches associated with the common identifier is determined to result from a user capacitively coupled to the user identification electrode 130. The control circuitry is configured to, when a plurality of touches is detected at the same time (e.g., when two touches are detected at positions which overlie the same receive electrode 102), determine which of the plurality of touches result from a user capacitively coupled to the user identification electrode 130 based on the common identifier associated with each of the plurality of touches. As described above, the touch tracking module therefore provides the ability for the control circuitry to differentiate between touches detected at the same time and that overlie the receive electrode 102, particularly when there is also detected the signal from the user identification electrode 130.

The above disclosure has also focused on driving a user identification electrode 130 for each and every discrete time period (i.e., applying the techniques of FIG. 7a to 7d). However, it should be appreciated that a touch-sensitive system may employ combinations of different techniques, and in particular the techniques as described in FIG. 5a to 5d where it is only the drive electrodes 101 that are driven in each discrete time period (rather than additionally the user identification electrode 130). For example, a touch sensitive system in some implementations is configured to apply the techniques of FIGS. 5a to 5d, whereby a group of N drive electrodes (with N being equal to one of 2, 4, 8, 12, 16, 20, 24, 28, 32, etc.) are drive at any one time to obtain a plurality of N measurements over N discrete time periods. When a touch is detected using the approach of FIGS. 5a to 5d, then the touch sensitive apparatus may switch to utilising the technique as described in FIG. 7a to 7d. The processing circuitry 106 may not determine the presence of a touch unless the touch is present in at least a plurality of complete scans of the electrode array (e.g., to account for any noise fluctuations). In this example, the measurement circuitry 105 and processing circuitry 106 (the control circuitry) may perform a first scan utilising the technique of FIGS. 5a to 5d, then if a touch is detected in the first scan, utilise the technique of FIGS. 7a to 7d for the second scan to both confirm the detected touch is genuine (i.e., not as a result of a noise fluctuation) and to ascertain whether the touch originates from the user coupled to the user identification electrode 130 or not. In yet some further implementations, the measurement circuitry 105 and processing circuitry 106 may be configured to target only the relevant drive and receive electrodes of the electrode array once a touch has been detected in the second scan. For instance, if a touch is identified at intersection point 102-1, the second scan may be performed using the technique of FIGS. 7a to 7d on drive electrodes 1 to 3 with user identification electrode 130 also being driven as described above. Combinations of the techniques of FIGS. 5a to 5d and 7a to 7d may provide yet further improvements in general performance of the touch sensitive system as well as the ability to distinguish whether a touch originates form a user coupled to the user identification electrode 130.

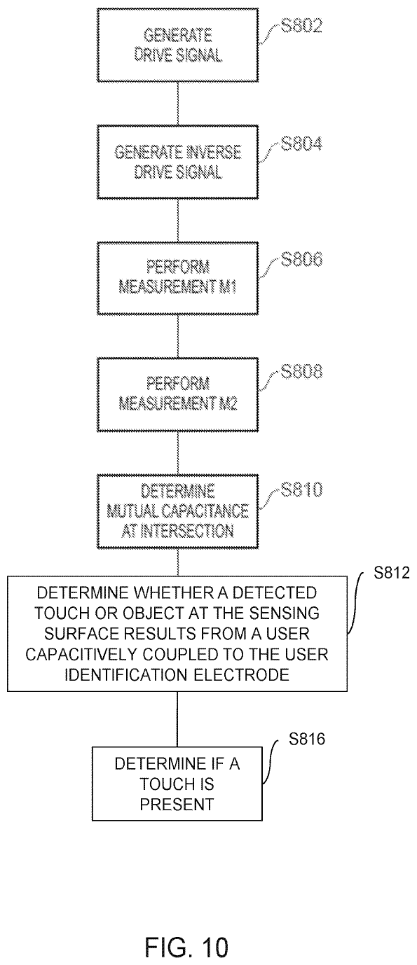

FIG. 10 describes an exemplary method of operating a touch sensitive system, such as the touch sensitive system described in FIGS. 6 and 7a to 7d, in accordance with the principles of the present disclosure.

The method begins at step S802 where drive circuitry 112 generates the drive signal (i.e., signal 1). At step S804, the drive circuitry 112 generates the inverse drive signal (i.e., signal 2). Step S804 may utilise the drive signal generated at step S802 as described previously.

At step S806, the method performs measurement M1 on a receive electrode that intersects at least a first drive electrode (e.g., at least drive electrodes 1 to 3 of FIGS. 7a to 7d). This measurement M1 is performed for a first time period. As described previously, at step S806 the measurement circuitry 105 applies at least one of signal 1 or signal 2 to a first drive electrode in addition to applying at least one of signal 1 or signal 2 to the user identification electrode 130, and in instances where there are multiple drive electrodes, the measurement circuitry 105 applies a combination of the first and second drive signals to the multiple drive electrodes (with each drive electrode receiving one or the other of the first and second drive signals). More generally, at step S806, the control circuitry is configured to identify a set of N electrodes of the sensing element, where N is an integer greater than or equal to one, with the set of N electrodes including the at least one (drive) electrode. The drive signal(s) (signal 1 and/or signal 2) couple to the receive electrode 102 and measurement circuitry 105 performs measurement M1. The method proceeds then to step S808.

At step S808, the method performs measurement M2 on the same receive electrode 102. This measurement M2 is performed for a second time period, which in this implementation is of the same duration as the first time period. Ones of the drive signals (signal 1 or signal 2) are applied to the at least one drive electrode and the user identification electrode 130. As described previously, in the case of multiple drive electrodes, the measurement circuitry 105 applies a combination of the first and second drive signals to the multiple drive electrodes (with each drive electrode receiving one or the other of the first and second drive signals). However, it should be appreciated that the drive signal applied to at least one (drive) electrode (of the identified set of N drive electrodes) or the user identification electrode 130 in a first time period is different to the drive signal applied to the at least one (drive) electrode or the user identification electrode 130 in the second time period.

As above, the drive signal(s) (signal 1 and/or signal 2) couple to the receive electrode 102 from the respective electrode(s), and measurement circuitry 105 performs measurement M2.

Although not shown in FIG. 10, the method may perform further measurements (essentially as described at steps S806 and S808) depending upon the number of drive electrodes included in the set of drive electrodes. That is, for a set of N drive electrodes, the measurement circuitry 105 performs N plus the number of user identification electrodes 130, M, provided that M plus N is an integer selected from the sequence 2, 4, 8, 12, 16, 20, 24, 28, 32 etc., as described above. Additionally, as described above, the control circuitry may obtain measurements across the whole sensor element 100 (i.e., across all intersection points) using any technique as described previously (e.g., scanning a plurality of groups of N drive electrodes and/or scanning each receive electrode sequentially or in parallel).

Once the measurements have been obtained, the method proceeds then to step S810 where the processing circuitry 106, using the obtained measurements, determines a value or signal indicative of the mutual capacitance at each of the intersection points between the drive electrodes of set of N drive electrodes and the receive electrode 102. As described above, the processing circuitry may use equations (15) to (17), or variations thereof, depending on the number of drive electrodes in the set of electrodes/of the electrode array 101, 102.

At step S812, using the measurements obtained above, the processing circuitry 106 is also configured to determine a value or signal indicative of whether a detected touch or object at the sensing surface results from a user capacitively coupled to the user identification electrode 130. As described above, the processing circuitry may use equation (18), or variations thereof, depending on the number of drive electrodes in the set of electrodes (and hence the number of measurements made) to determine the value or signal indicative of whether a detected touch or object at the sensing surface results from a user capacitively coupled to the user identification electrode 130. At this point, the method of FIG. 10 provides sufficient information to the processing circuitry 106 to enable the processing circuitry to determine whether or not a touch (or object) results from a user capacitively coupled to the user identification electrode 130.

It should be appreciated that the above described method is an example method only and depending on the specific implementations at hand the method may be adapted, for example, the ordering of the steps may be modified. Additionally as noted above, there may be additional modification such that the technique of e.g., FIG. 5a to 5d is implemented and only when a touch is detected is the method of FIG. 7a to 7d implemented.

Further, it should be appreciated that while the drive signal is described as a sinusoidal signal (either signal 1 or signal 2), the principles of the described technique are equally applicable to other signal waveforms for which an inverse waveform of signal 1 can be generated as signal 2, e.g., a square wave, whereby the inverse signal varies in opposition to the initial signal.

In addition, it should be appreciated that the above description focuses on the idea of measuring mutual capacitances from an electrode array, e.g., the capacitance between a first drive electrode and a receive electrode. However, the abovementioned technique can be applied to a system configured to measure the self-capacitance of a given (drive) electrode. In respect of self-capacitance, drive circuitry (such as drive circuitry 112) is configured to generate and apply a drive signal to a drive electrode (e.g., such as drive electrode 101) which will cause an electric field to form around the drive electrode. This field couples through the space around the electrode back to measurement circuitry (such as measurement circuitry 105) via numerous conductive return paths that are part of the nearby circuitry of the sensor element and the product housing or physical elements from the nearby surroundings etc., so completing a capacitive circuit. The overall sum of return paths is typically referred to as the “free space return path” in an attempt to simplify an otherwise hard-to-visualize electric field distribution. The important point to realise is each electrode is driven from a single explicit electrical terminal; the other terminal is the capacitive connection via this “free space return path”. The capacitance measured by the measurement circuitry is the “self-capacitance” of the sensor electrode (and connected tracks) that is being driven relative to free space (or Earth as it is sometimes called) i.e. the “self-capacitance” of the relevant sensor electrode. Touching or approaching the electrode with a conductive element, such as a human finger, causes some of the field to couple via the finger through the connected body, through free space and back to the measurement circuitry. This extra return path can be relatively strong for large objects (such as the human body), and so can give a stronger coupling of the electrode's field back to the measurement circuitry; touching or approaching the electrode hence increases the self-capacitance of the electrode. The measurement circuitry is configured to sense this increase in capacitance. The increase is strongly proportional to the area of the applied touch and is normally weakly proportional to the touching body's size (the latter typically offering quite a strong coupling and therefore not being the dominant term in the sum of series connected capacitances). Therefore, broadly speaking, a touch-sensitive apparatus configured to measure a self-capacitance of a drive electrode of an electrode array, drives a drive electrode with a drive signal (such as the first drive signal 1 or second drive signal 2) and the measurement circuitry measures a self-capacitance of the drive electrode. This is unlike the mutual capacitance technique discussed above whereby the capacitive coupling that is measured is between the driven electrode and the receive electrode (i.e., another electrode of the electrode array).

It should be appreciated that a touch-sensitive apparatus may be configured to operate in either the self-capacitance or mutual capacitance measurement modes. A touch-sensitive apparatus may be configured to operate exclusively in one of these measurement modes, or have the functionality to switch between measurement modes.

Thus there has been described a touch-sensitive system, the system including: a sensing element comprising at least one electrode, the sensing element comprising a sensing surface for sensing the interaction of a touch or object with the sensing element; a user identification electrode arranged so as to be capable of capacitively coupling to a user of the touch-sensitive system; drive circuitry configured to generate a first drive signal and a second drive signal, wherein the first and second drive signals are the inverse of one another; and control circuitry. The control circuitry is configured to: identify a set of N electrodes of the sensing element, where N is an integer greater than or equal to one, the set of N electrodes including the at least one electrode; apply one of the first drive signal or second drive signal to each of the set of N electrodes and to the user identification electrode over a plurality of discrete time periods, wherein the drive signal applied to the at least one electrode or the user identification electrode in a first time period of the plurality of discrete time periods is different to the drive signal applied to the at least one electrode or the user identification electrode in a second time period of the plurality of discrete time periods; obtain a measurement from the sensing element in each of the plurality of discrete time periods; and determine whether a detected touch or object at the sensing surface results from a user capacitively coupled to the user identification electrode based on the obtained measurements from the sensing element in each of the plurality of discrete time periods. Also disclosed is a host system comprising the touch-sensitive system, a vehicle comprising the host system, and a method of operating a touch-sensitive system.

Further particular and preferred aspects of the present invention are set out in the accompanying independent and dependent claims. It will be appreciated that features of the dependent claims may be combined with features of the independent claims in combinations other than those explicitly set out in the claims.

1. A touch-sensitive system, the system comprising:
a sensing element comprising at least one electrode, the sensing element comprising a sensing surface for sensing the interaction of a touch or object with the sensing element;
a user identification electrode arranged so as to be capable of capacitively coupling to a user of the touch-sensitive system;
drive circuitry configured to generate a first drive signal and a second drive signal, wherein the first and second drive signals are the inverse of one another; and
control circuitry configured to:
identify a set of N electrodes of the sensing element, where N is an integer greater than or equal to one, the set of N electrodes including the at least one electrode;
apply one of the first drive signal or second drive signal to each of the set of N electrodes and to the user identification electrode over a plurality of discrete time periods, wherein the drive signal applied to the at least one electrode or the user identification electrode in a first time period of the plurality of discrete time periods is different to the drive signal applied to the at least one electrode or the user identification electrode in a second time period of the plurality of discrete time periods;
obtain a measurement from the sensing element in each of the plurality of discrete time periods; and
determine whether a detected touch or object at the sensing surface results from a user capacitively coupled to the user identification electrode based on the obtained measurements from the sensing element in each of the plurality of discrete time periods.

2. The system of claim 1, wherein determining whether a detected touch or object at the sensing surface results from a user capacitively coupled to the user identification electrode based on the obtained measurements from the sensing element in each of the plurality of discrete time periods includes combining the measurements obtained in each of the discrete time periods to provide a resultant signal, the resultant signal indicative of the capacitive coupling between the sensing element and the user identification electrode, such that when a user capacitively coupled to the user identification electrode interacts with the sensing surface, the resultant signal changes.

3. The system of claim 2, wherein determining whether a detected touch or object at the sensing surface results from a user capacitively coupled to the user identification electrode includes determining whether the resultant signal is at or increases above a threshold value.

4. The system of claim 1, wherein the number of discrete time periods is greater than N.

5. The system of claim 4, wherein number of discrete time periods is greater than N by one.

6. The system of claim 1, wherein the number of discrete time periods is selected from the sequence comprising: 2, 4, 8, 12, 16, 20, 24, 28, 32, etc.

7. The system of claim 1, wherein for each of the plurality of discrete time periods, the control circuitry is configured to apply different combinations of one of the first drive signal or second drive signal to each of the set of N electrodes and the user identification electrode.

8. The system of claim 1, wherein the control circuitry is configured to output a signal indicative of whether the detected touch or object results from a user capacitively coupled to the user identification electrode, such that a host system receiving the output signal is capable of performing different actions depending on whether the detected touch or object resulted from a user capacitively coupled to the user identification electrode or not.

9. The system of claim 1, wherein the control circuitry is further configured to determine whether a touch or object is detected at the sensing surface based on the obtained measurements from the sensing element in each of the plurality of discrete time periods.

10. The system of claim 9, wherein the control circuitry is configured to determine one or more resultant signals indicative of a capacitance associated with the set of N electrodes based on combinations of the measurements obtained in each of the discrete time periods, wherein optionally, the control circuitry configured to determine whether a touch or object is detected at the sensing surface includes determining whether the one or more resultant signals surpass a threshold value, the threshold value being a fixed value or a value set based on a resultant signal obtained in the absence of a touch or object at the sensing surface.

11. (canceled)

12. The system of claim 1, wherein the sensing element comprises a receive electrode, wherein the set of N electrodes is capable of capacitively coupling to the receive electrode, and wherein the measurements obtained at each of the discrete time periods are performed on the receive electrode of the sensing element, wherein optionally, the control circuitry is configured to determine a resultant signal indicative of a mutual capacitance between the at least one electrode of the set of N electrodes and the receive electrode based on based on the obtained measurements from the receive electrode of the sensing element in each of the plurality of discrete time periods

13. (canceled)

14. The system of claim 1, wherein the user identification electrode is remote from the sensing element, wherein optionally, the user identification electrode is coupled to a user object arranged such that the user makes physical contact with the user object in use of the touch-sensitive system.

15. (canceled)

16. The system of claim 1, wherein the touch-sensitive system further comprises a touch tracking module configured to associate touches detected at a plurality of different times with a common identifier signifying that the touches detected at a plurality of different times correspond to a common touch applied by a user of the touch-sensitive system.

17. The system of claim 16, wherein determining whether a detected touch or object at the sensing surface results from a user capacitively coupled to the user identification electrode is further based on information from the touch tracking module.

18. The system of claim 16, wherein the touch tracking module is configured to associate a common identifier with a flag indicative of a touch or a plurality of touches originating from a user capacitively coupled to the user identification electrode, wherein the touch tracking module is configured to associate the flag with the common identifier if the earliest touch in time of the touches associated with the common identifier is determined to result from a user capacitively coupled to the user identification electrode.

19. The system of claim wherein the control circuitry is configured to, when a plurality of touches is detected at the same time, determine which of the plurality of touches result from a user capacitively coupled to the user identification electrode based on the common identifier associated with each of the plurality of touches.

20. A host system comprising the touch-sensitive system of claim 1, further comprising host system processing circuitry communicatively coupled to the control circuitry of the touch-sensitive system, wherein the host system processing circuitry is configured to receive an output signal from the control circuitry of the touch-sensitive system indicative of whether a detected touch or object results from a user capacitively coupled to the user identification electrode.

21. The host system of claim 20, wherein the host system processing circuitry is configured to cause a first action to be performed in the event that the output signal indicates the detected touch or object results from a user capacitively coupled to the user identification electrode, and wherein the host system processing circuitry is configured to cause a second action to be performed in the event that the output signal indicates the detected touch or object does not result from a user capacitively coupled to the user identification electrode, wherein optionally, the first action is to disregard the detected touch or object.

22. (canceled)

23. A vehicle comprising the host system of claim 20, wherein the user identification electrode is mounted to an electrically conductive component of a seat, wherein the electrically conductive component is arranged to contact a user when the user is sitting in the seat.

24. A method of operating a touch-sensitive system, the system comprising a sensing element comprising at least one electrode, the sensing element comprising a sensing surface for sensing the interaction of a touch or object with the sensing element; a user identification electrode arranged so as to be capable of capacitively coupling to a user of the touch-sensitive system; and drive circuitry configured to generate a first drive signal and a second drive signal, wherein the first and second drive signals are the inverse of one another, wherein the method comprises:
identifying a set of N electrodes of the sensing element, where N is an integer greater than or equal to one, the set of N electrodes including the at least one electrode;
applying one of the first drive signal or second drive signal to each of the set of N electrodes and to the user identification electrode over a plurality of discrete time periods, wherein the drive signal applied to the user identification electrode in a first time period of the plurality of discrete time periods is different to the drive signal applied to the user identification electrode in a second time period of the plurality of discrete time periods;
obtaining a measurement from the sensing element in each of the plurality of discrete time periods; and
determining whether a detected touch or object at the sensing surface results from a user capacitively coupled to the user identification electrode based on the obtained measurements from the sensing element in each of the plurality of discrete time periods.
